(19) United States
(12) Patent Application Publication
(10) Pub. No.: US 2024/0324310 A1
(43) Pub. Date: Sep. 26, 2024

(54) DISPLAY APPARATUS AND METHOD OF MANUFACTURING THE SAME

(71) Applicant: Samsung Display Co., Ltd., Yongin-si (KR)

(72) Inventor: Jaesik Kim, Yongin-si (KR)

(73) Assignee: Samsung Display Co., Ltd., Yongin-si (KR)

(21) Appl. No.: 18/585,712

(22) Filed: Feb. 23, 2024

(30) Foreign Application Priority Data
Mar. 24, 2023 (KR) 10-2023-0039202
Jun. 16, 2023 (KR) 10-2023-0077713

(51) Int. Cl. H10K 59/122; H10K 59/12

(52) U.S. Cl. CPC H10K 59/122; H10K 59/1201

(57) ABSTRACT

A display apparatus includes a first pixel electrode and a second pixel electrode spaced apart from each other and disposed on a substrate, a pixel definition layer including a first inner surface defining a first opening exposing a portion of the first pixel electrode and a second inner surface defining a second opening exposing a portion of the second pixel electrode, a first lyophobic pattern covering the first inner surface and a portion of an upper surface of the pixel definition layer adjacent to the first inner surface and including a lyophobic material, and an opposite electrode disposed on the first pixel electrode and the second pixel electrode. The first lyophobic pattern partially surrounds the first opening in a plan view.

### CROSS REFERENCE TO RELATED APPLICATION(S)

This application claims priority to and benefits of Korean Patent Application No. 10-2023-0039202 under 35 U.S.C. § 119, filed on Mar. 24, 2023, and Korean Patent Application No. 10-2023-0077713 under 35 U.S.C. § 119, filed on Jun. 16, 2023, in the Korean Intellectual Property Office (KIPO), the entire contents of which are incorporated herein by reference.

### BACKGROUND

### 1. Technical Field

Embodiments relate to a display apparatus in which a defect occurrence possibility in a manufacturing process of the display apparatus is reduced and a method of manufacturing the same.

### 2. Description of the Related Art

In general, an emission layer included in an organic light emitting display apparatus is formed through a solution process. The solution process is performed by producing a solution by mixing an organic material constituting the emission layer with a solvent and dropping the solution to an opening of a pixel definition layer.

In the process, in case that the pixel definition layer is lyophilic, a portion of the solution including the organic material constituting the emission layer spreads widely on an upper surface of the pixel definition layer. In a process of drying the solution including the organic material constituting the emission layer, a portion of the solution including the organic material constituting the emission layer may remain on the upper surface of the pixel definition layer, and a thickness of the formed emission layer may not be uniform. In order to overcome this limitation, a pixel definition layer including a fluorine-based compound is used or a plasma treatment is performed on the pixel definition layer.

However, in such a display apparatus of the related art, in case that a pixel definition layer including a fluorine-based compound is used or a plasma treatment is performed on the pixel definition layer, an adhesive force between the pixel definition layer and a layer disposed on the pixel definition layer may be reduced.

### SUMMARY

The disclosure provides a display apparatus in which a defect occurrence possibility in a manufacturing process thereof is reduced and a method of manufacturing the same. However, these problems are merely examples and the scope of the disclosure is not limited thereto.

Additional aspects will be set forth in part in the description which follows and, in part, will be apparent from the description, or may be learned by practice of the embodiments of the disclosure.

According to an embodiment, a display apparatus may include a first pixel electrode and a second pixel electrode spaced apart from each other and disposed on a substrate, a pixel definition layer including a first inner surface defining a first opening exposing a portion of the first pixel electrode and a second inner surface defining a second opening exposing a portion of the second pixel electrode, a first lyophobic pattern covering the first inner surface and a portion of an upper surface of the pixel definition layer adjacent to the first inner surface and including a lyophobic material, and an opposite electrode disposed on the first pixel electrode and the second pixel electrode. The first lyophobic pattern may partially surround the first opening in a plan view.

The first lyophobic pattern may include a first-first lyophobic pattern and a first-second lyophobic pattern spaced apart from each other.

Each of the first-first lyophobic pattern and the first-second lyophobic pattern may surround a portion of the first opening in a plan view.

A portion of an upper surface of the pixel definition layer between the first-first lyophobic pattern and the first-second lyophobic pattern may directly contact the opposite electrode.

The display apparatus may further include a second lyophobic pattern covering the second inner surface and a portion of an upper surface of the pixel definition layer adjacent to the second inner surface and including a lyophobic material.

A portion of an upper surface of the pixel definition layer between the first lyophobic pattern and the second lyophobic pattern may directly contact the opposite electrode.

The second lyophobic pattern may include a second-first lyophobic pattern and a second-second lyophobic pattern spaced apart from each other, and a portion of an upper surface of the pixel definition layer between the second-first lyophobic pattern and the second-second lyophobic pattern may directly contact the opposite electrode.

The display apparatus may further include a first emission layer interposed between the first pixel electrode and the opposite electrode, and a second emission layer interposed between the second pixel electrode and the opposite electrode.

The lyophobic material may include a self-assembled monolayer.

The first lyophobic pattern may be spaced apart from the first pixel electrode.

According to embodiments, a method of manufacturing a display apparatus may include forming, on a substrate, a first pixel electrode and a second pixel electrode spaced apart from each other, forming, on the substrate, a pixel definition layer including a first inner surface defining a first opening exposing a portion of the first pixel electrode and a second inner surface defining a second opening exposing a portion of the second pixel electrode, forming a preliminary lyophobic pattern layer including a lyophobic material on the first pixel electrode, the second pixel electrode, and the pixel definition layer, forming, by removing a portion of the preliminary lyophobic pattern layer, a first lyophobic pattern covering the first inner surface and a portion of an upper surface of the pixel definition layer adjacent to the first inner surface, including a lyophobic material, and partially surrounding the first opening in a plan view, and forming an opposite electrode on the first pixel electrode and the second pixel electrode.

The first lyophobic pattern may include a first-first lyophobic pattern and a first-second lyophobic pattern spaced apart from each other.

The forming of the first lyophobic pattern may include forming the first lyophobic pattern such that each of the first-first lyophobic pattern and the first-second lyophobic pattern surrounds a portion of the first opening in a plan view.

The forming of the opposite electrode may include forming the opposite electrode such that a portion of an upper surface of the pixel definition layer between the first-first lyophobic pattern and the first-second lyophobic pattern directly contacts the opposite electrode.

The forming of the first lyophobic pattern may include forming, by removing a portion of the preliminary lyophobic pattern layer, a second lyophobic pattern covering the second inner surface and a portion of an upper surface of the pixel definition layer adjacent to the second inner surface.

The forming of the opposite electrode may include forming the opposite electrode such that a portion of an upper surface of the pixel definition layer between the first lyophobic pattern and the second lyophobic pattern directly contacts the opposite electrode.

The second lyophobic pattern may include a second-first lyophobic pattern and a second-second lyophobic pattern spaced apart from each other, and the forming of the opposite electrode may include forming the opposite electrode such that a portion of an upper surface of the pixel definition layer between the second-first lyophobic pattern and the second-second lyophobic pattern directly contacts the opposite electrode.

The method may further include forming a first emission layer in the first opening and forming a second emission layer in the second opening. The forming of the first emission layer and the forming of the second emission layer may be performed between the forming of the first lyophobic pattern and the forming of the opposite electrode.

The lyophobic material may include a self-assembled monolayer.

The forming of the first lyophobic pattern may include forming the first lyophobic pattern such that the first lyophobic pattern is spaced apart from the first pixel electrode.

Other aspects, features, and advantages other than those described above will become apparent from the following detailed description, the appended claims, and the accompanying drawings.

### BRIEF DESCRIPTION OF THE DRAWINGS

The above and other aspects, features, and advantages of embodiments of the disclosure will be more apparent from the following description taken in conjunction with the accompanying drawings, in which:

FIG. 1 is a schematic plan view illustrating a portion of a display apparatus according to an embodiment;

FIG. 2 is a schematic diagram of an equivalent circuit of a pixel circuit included in a display apparatus according to an embodiment;

FIG. 3 is a schematic enlarged plan view illustrating region A of the display apparatus of FIG. 1;

FIG. 4 is a schematic cross-sectional view illustrating a cross-section of the display apparatus taken along line I-I′ of FIG. 3;

FIG. 5 is a schematic diagram illustrating a self-assembled monolayer material;

FIG. 6 is a schematic cross-sectional view illustrating a cross-section of the display apparatus taken along line II-II′ of FIG. 3;

FIG. 7 is a schematic cross-sectional view illustrating a portion of a display apparatus according to an embodiment;

FIG. 8 is a schematic plan view illustrating a display apparatus according to an embodiment;

FIGS. 9 to 11 are schematic plan views illustrating a display apparatus according to an embodiment;

FIGS. 12 to 19 are schematic cross-sectional views illustrating a process of manufacturing the display apparatus of FIG. 4; and

FIG. 20 is a schematic cross-sectional view illustrating a display apparatus manufacturing method according to an embodiment.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Reference will now be made in detail to embodiments, examples of which are illustrated in the accompanying drawings, wherein like reference numerals refer to like elements throughout. In this regard, the embodiments may have different forms and should not be construed as being limited to the descriptions set forth herein. Accordingly, the embodiments are merely described below, by referring to the figures, to explain aspects of a description. As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or.” Throughout the disclosure, the expression “at least one of a, b, and c” and “at least one selected from the group consisting of a, b, and c” indicates only a, only b, only c, both a and b, both a and c, both b and c, all of a, b, and c, or variations thereof.

The disclosure may include various embodiments and modifications, and embodiments thereof are illustrated in the drawings and will be described herein in detail. The advantages and features of the disclosure and the accomplishing methods thereof will become apparent from the embodiments described below in detail with reference to the accompanying drawings. However, a disclosure is not limited to the embodiments described below and may be embodied in various modes.

The terminology used herein is for the purpose of describing particular embodiments and is not intended to be limiting. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

It will be understood that although terms such as “first” and “second” may be used herein to describe various elements, these elements should not be limited by these terms and these terms are only used to distinguish one element from another element. Thus, a first element discussed below could be termed a second element without departing from the teachings of the disclosure.

As used herein, the singular forms “a,” “an,” and “the” are intended to include the plural forms as well, unless the context clearly indicates otherwise.

Also, it will be understood that the terms “comprise,” “include,” and “have” used herein specify the presence of stated features, components, elements, features, integers, steps, operations, and/or group thereof, but do not preclude the presence or addition of one or more other features, components, elements, features, integers, steps, operations, and/or group thereof.

It will be understood that in case that an element such as a layer, a region, or a plate is referred to as being “on” another element, it may be “directly on” the element or may be “indirectly on” the other element with one or more intervening elements therebetween.

It will be understood that in case that a layer, region, or component is referred to as being “connected to” another layer, region, or component, it may be “directly connected to” the other layer, region, or component or may be “indirectly connected to” the other layer, region, or component with one or more intervening layers, regions, or components therebetween. When, however, an element or layer is referred to as being “directly on” or “directly connected to” another element or layer, there are no intervening elements or layers present. For example, it will be understood that in case that a layer, region, or component is referred to as being “electrically connected to” another layer, region, or component, it may be “directly electrically connected to” the other layer, region, or component and/or may be “indirectly electrically connected to” the other layer, region, or component with one or more intervening layers, regions, or components therebetween.

When a component is described herein to “connect” another component to the other component or to be “connected to” other components, the components may be connected to each other as separate elements, or the components may be integral with each other.

Throughout the specification, when an element is referred to as being “connected” to another element, the element may be “directly connected” to another element, or “electrically connected” to another element with one or more intervening elements interposed therebetween. Also, when an element is referred to as being “in contact” or “contacted” or the like to another element, the element may be in “electrical contact” or in “physical contact” with another element; or in “indirect contact” or in “direct contact” with another element.

Spatially relative terms, such as “under,” “lower,” “upper,” “over,” “higher,” “side,” and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the example term “below” can encompass both an orientation of above and below. Furthermore, the apparatus may be otherwise oriented (e.g., rotated 90 degrees or at other orientations), and, as such, the spatially relative descriptors used herein interpreted accordingly.

As used herein, the x-axis direction, the y-axis direction, and the z-axis direction are not limited to three axes of the rectangular coordinate system, and may be interpreted in a broader sense. For example, the x-axis direction, the y-axis direction, and the z-axis direction may be perpendicular to one another or may represent different directions that are not perpendicular to one another.

In case that an embodiment may be implemented differently, a particular process order may be performed differently from the described order. For example, two processes described in succession may be performed substantially at the same time or may be performed in an order opposite to the described order.

Hereinafter, embodiments will be described in detail with reference to the accompanying drawings, and in the following description, like reference numerals will denote like elements and redundant descriptions thereof will be omitted for conciseness. Sizes of components in the drawings may be exaggerated for convenience of description. For example, because the sizes and shapes of components in the drawings are arbitrarily illustrated for convenience of description, the disclosure is not limited thereto.

Unless otherwise specified, the illustrated embodiments are to be understood as providing example features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the disclosure.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

The display surface may be parallel to a surface defined by a first direction (e.g., the x-axis direction or the −x-axis direction) and a second direction (e.g., the y-axis direction or the −y-axis direction). A normal direction of the display surface, i.e., a thickness direction of the display apparatus 1, may indicate a third direction (e.g., the z-axis direction or the −z-axis direction). In this specification, an expression of “when viewed from the top or in a plan view” may represent a case when viewed in the third direction. Hereinafter, a front surface (or a top surface) and a rear surface (or a bottom surface) of each of layers or units may be distinguished by the third direction. However, directions indicated by the first, second, and third directions may be a relative concept, and converted with respect to each other, e.g., converted into opposite directions.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

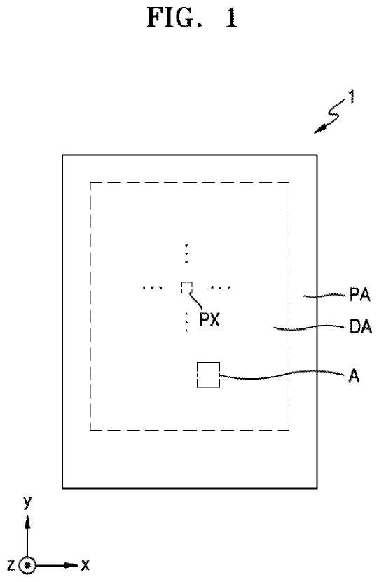

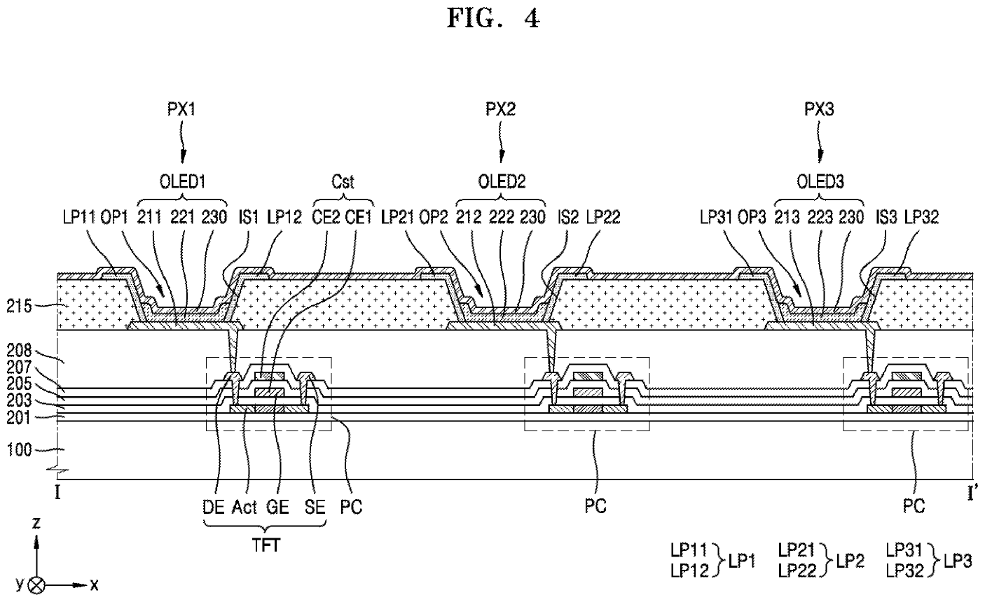

FIG. 1 is a schematic plan view illustrating a portion of a display apparatus 1 according to an embodiment. Referring to FIG. 1, the display apparatus 1 may include a display area DA in which multiple pixels PX are arranged and a peripheral area PA located adjacent to the display area DA. For example, the peripheral area PA may surround at least a portion of the display area DA. For example, the peripheral area PA may entirely surround the display area DA. The display apparatus 1 may include a substrate (see, e.g., 100 of FIG. 4). The substrate (see, e.g., 100 of FIG. 4) included in the display apparatus 1 may include the display area DA and the peripheral area PA.

Each pixel PX of the display apparatus 1 may be an area capable of emitting light of a color (e.g., a certain or selectable color), and the display apparatus 1 may provide an image by using light emitted from the pixels PX. For example, each pixel PX may emit red, green, or blue light.

Referring to FIG. 1, the display area DA may have a polygonal shape such as a tetragonal shape or the like in a plan view. In an embodiment, the display area DA may have a rectangular shape in which the horizontal length is greater than the vertical length. In another embodiment, the display area DA may have a rectangular shape in which the horizontal length is less than the vertical length. In another embodiment, the display area DA may have a square shape. In another embodiment, the display area DA may have various shapes such as an elliptical shape, a circular shape, or the like.

The peripheral area PA may be a non-display area in which pixels PX are not arranged. A driver or the like for providing an electrical signal or power to the pixels PX may be arranged in the peripheral area PA. The peripheral area PA may include pads (not illustrated) to which various electronic elements, printed circuit boards, or the like are electrically connected. The pads may be spaced apart from each other in the peripheral area PA and may be electrically connected to a printed circuit board, an integrated circuit element, or the like.

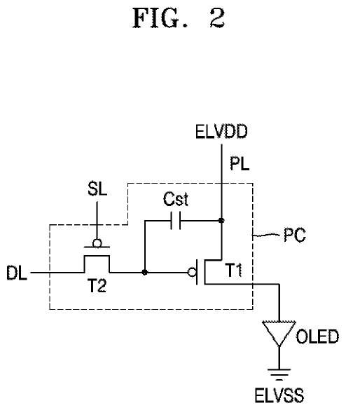

FIG. 2 is a schematic diagram of an equivalent circuit of a pixel circuit PC included in the display apparatus 1 according to an embodiment. The pixel circuit PC may be electrically connected to an organic light emitting diode OLED, and one organic light emitting diode OLED may correspond to one pixel PX.

The pixel circuit PC may include a first transistor T1, a second transistor T2, and a storage capacitor Cst. The second transistor T2 may be a switching transistor. As a switching transistor, the second transistor T2 may be electrically connected to a scan line SL and a data line DL and may be turned on by a switching signal input from the scan line SL and transmit a data signal input from the data line DL to the first transistor T1. An end of the storage capacitor Cst may be electrically connected to the second transistor T2 and another end of the storage capacitor Cst may be electrically connected to a driving voltage line PL, and the storage capacitor Cst may store a voltage corresponding to the difference between a voltage received from the second transistor T2 and a driving power voltage ELVDD supplied to the driving voltage line PL.

The first transistor T1 may be a driving transistor. As a driving transistor, the first transistor T1 may be electrically connected to the driving voltage line PL and the storage capacitor Cst and may control a level of a driving current flowing from the driving voltage line PL to the organic light emitting diode OLED in response to a voltage value stored in the storage capacitor Cst. The organic light emitting diode OLED may emit light with a brightness (a certain or selectable brightness) according to the driving current. An opposite electrode of the organic light emitting diode OLED may be supplied with an electrode power voltage ELVSS.

Although FIG. 2 illustrates that the pixel circuit PC includes two transistors and one storage capacitor, the disclosure is not limited thereto. The number of transistors and the number of storage capacitors may be variously modified according to a design of the pixel circuit PC.

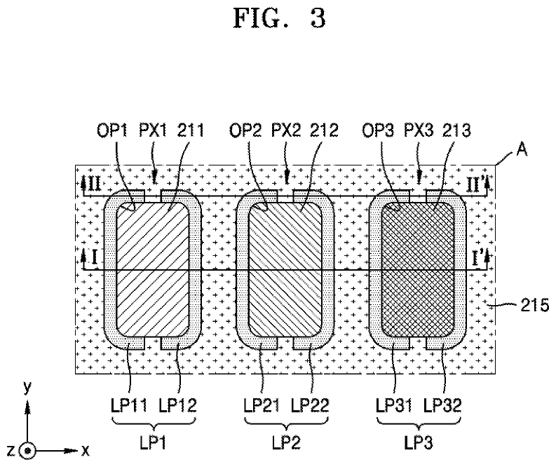

FIG. 3 is a schematic enlarged plan view illustrating region A of the display apparatus 1 of FIG. 1. For convenience, FIG. 3 illustrates a plan view over (or on) a pixel definition layer 215. For convenience of description, FIG. 3 illustrates lyophobic (or liquid-repellent) patterns LP1, LP2, and LP3 disposed (e.g., disposed together) on the pixel definition layer 215.

Referring to FIG. 3, multiple pixels PX may be arranged in the display area (see, e.g., DA of FIG. 2) of the substrate (sec., e.g., 100 of FIG. 4). For example, the pixels PX may be arranged on the substrate (see, e.g., 100 of FIG. 4) in the display area DA. Each of the pixels PX may be a subpixel and may include a display element such as an organic light emitting diode (see, e.g., OLED of FIG. 2). For example, the pixel PX may emit red, green, or blue light. For example, the pixel PX may be a first pixel PX1 emitting red light, a second pixel PX2 emitting green light, or a third pixel PX3 emitting blue light. The red light may be light belonging to a wavelength band in a range of about 580 nm to about 780 nm, the green light may be light belonging to a wavelength band in a range of about 495 nm to about 580 nm, and the blue light may be light belonging to a wavelength band in a range of about 400 nm to about 495 nm.

A first pixel electrode 211 included in the first pixel PX1, a second pixel electrode 212 included in the second pixel PX2, and a third pixel electrode 213 included in the third pixel PX3 may be arranged in the display area (see, e.g., DA of FIG. 2). For example, the first pixel electrode 211, the second pixel electrode 212, and the third pixel electrode 213 may be spaced apart from each other in a first direction (e.g., the x-axis direction or the −x-axis direction) in a plan view. In an embodiment, referring to FIG. 3, the first pixel electrode 211, the second pixel electrode 212, and the third pixel electrode 213 may have a same size in a plan view. In another embodiment, the first pixel electrode 211, the second pixel electrode 212, and the third pixel electrode 213 may have different sizes.

The pixel definition layer 215 may be disposed on the first pixel electrode 211, the second pixel electrode 212, and the third pixel electrode 213. For example, the pixel definition layer 215 may be disposed on a portion of the first to third pixel electrodes 211, 212, and 213 (see, e.g., FIG. 4). The pixel definition layer 215 may include a first opening OP1, a second opening OP2, and a third opening OP3. The first opening OP1 and the second opening OP2 may be located adjacent to each other in the first direction (e.g., the x-axis direction or the −x-axis direction), and the third opening OP3 may be located in an opposite direction to the first opening OP1 with the second opening OP2 interposed between the first opening OP1 and the third opening OP3. The first opening OP1 may expose a portion (e.g., a center portion) of the first pixel electrode 211, the second opening OP2 may expose a portion (e.g., a center portion) of the second pixel electrode 212, and the third opening OP3 may expose a portion (e.g., a center portion) of the third pixel electrode 213. In an embodiment, referring to FIG. 3, the first opening OP1, the second opening OP2, and the third opening OP3 may have a same size. In another embodiment, the first opening OP1, the second opening OP2, and the third opening OP3 may have different sizes.

Although not illustrated in FIG. 3, emission layers emitting light may be located in the first opening OP1, the second opening OP2, and the third opening OP3 of the pixel definition layer 215. An opposite electrode may be disposed on the emission layers. A stack structure of the pixel electrode, the emission layer, and the opposite electrode may form an organic light emitting diode (see, e.g., OLED of FIG. 2). One opening of the pixel definition layer 215 may correspond to one organic light emitting diode (see, e.g., OLED of FIG. 2) and may define one emission area.

For example, an emission layer emitting red light may be arranged in the first opening OP1, and an emission area defined by the first opening OP1 may be defined as the first pixel PX1. An emission layer emitting green light may be arranged in the second opening OP2, and an emission area defined by the second opening OP2 may be defined as the second pixel PX2. An emission layer emitting blue light may be arranged in the third opening OP3, and an emission area defined by the third opening OP3 may be defined as the third pixel PX3. However, the disclosure is not limited thereto. In another embodiment, an emission layer emitting blue light or green light may be arranged in the first opening OP1, the second opening OP2, and the third opening OP3. The display apparatus 1 may include a light emitting panel and a color panel stacked in a thickness direction (e.g., the z-axis direction), and blue light or green light emitted from an emission layer of the light emitting panel may be transmitted through the emission layer or may be converted into red light, green light, and blue light while passing through the color panel.

A first lyophobic pattern LP1, a second lyophobic pattern LP2, and a third lyophobic pattern LP3 may be disposed on the pixel definition layer 215. In a plan view (in a direction perpendicular to the substrate (see, e.g., 100 of FIG. 4) (e.g., the z-axis direction)), lyophobic patterns LP1, LP2, and LP3 may be disposed on the pixel definition layer 215 and surround openings defined by the pixel definition layer 215. For example, in a plan view, the first lyophobic pattern LP1 may surround the first opening OP1, the second lyophobic pattern LP2 may surround the second opening OP2, and the third lyophobic pattern LP3 may surround the third opening OP3. Herein, “in a plan view” may mean a view in a direction perpendicular to the substrate (see, e.g., 100 of FIG. 4). For example, “B surrounding A in a plan view” may mean “B surrounding A when viewed in a direction perpendicular to the substrate (see, e.g., 100 of FIG. 4).”

Accordingly, the first lyophobic pattern LP1, the second lyophobic pattern LP2, and the third lyophobic pattern LP3 may be spaced apart from each other in the first direction (e.g., the x-axis direction or the −x-axis direction). For example, the first lyophobic pattern LP1 and the second lyophobic pattern LP2 may be located adjacent to each other in the first direction (e.g., the x-axis direction or the −x-axis direction), and the third lyophobic pattern LP3 may be located in an opposite direction to the first lyophobic pattern LP1 with the second lyophobic pattern LP2 interposed between the first lyophobic pattern LP1 and the third lyophobic pattern LP3.

In an embodiment, the first lyophobic pattern LP1 may include a first-first lyophobic pattern LP11 and a first-second lyophobic pattern LP12. For example, the first-first lyophobic pattern LP11 and the first-second lyophobic pattern LP12 may be sub lyophobic patterns of the first lyophobic pattern LP1. Each of the first-first lyophobic pattern LP11 and first-second lyophobic pattern LP12 may surround a portion of the first opening OP1 in a plan view. For example, referring to FIG. 3, in a plan view, the first-first lyophobic pattern LP11 may surround a left side of the first opening OP1, and the first-second lyophobic pattern LP12 may surround a right side of the first opening OP1.

The first-first lyophobic pattern LP11 and the first-second lyophobic pattern LP12 may be spaced apart from each other in the first direction (e.g., the x-axis direction or the −x-axis direction). For example, an end of the first-first lyophobic pattern LP11 disposed adjacent to the first-second lyophobic pattern LP12 may be spaced apart from an end of the first-second lyophobic pattern LP12 disposed adjacent to the first-first lyophobic pattern LP11, and another end of the first-first lyophobic pattern LP11 disposed adjacent to the first-second lyophobic pattern LP12 may be spaced apart from another end of the first-second lyophobic pattern LP12 disposed adjacent to the first-first lyophobic pattern LP11. For example, the first lyophobic pattern LP1 may partially surround the first opening OP1 in a plan view.

The second lyophobic pattern LP2 may include a second-first lyophobic pattern LP21 and a second-second lyophobic pattern LP22, and the third lyophobic pattern LP3 may include a third-first lyophobic pattern LP31 and a third-second lyophobic pattern LP32. For example, the second-first lyophobic pattern LP21 and the second-second lyophobic pattern LP22 may be sub lyophobic patterns of the second lyophobic pattern LP2, and the third-first lyophobic pattern LP31 and the third-second lyophobic pattern LP32 may be sub lyophobic patterns of the third lyophobic pattern LP3.

Each of the second-first lyophobic pattern LP21 and the second-second lyophobic pattern LP22 may surround a portion of the second opening OP2 in a plan view. For example, referring to FIG. 3, in a plan view, the second-first lyophobic pattern LP21 may surround a left side of the second opening OP2, and the second-second lyophobic pattern LP22 may surround a right side of the second opening OP2. The second-first lyophobic pattern LP21 and the second-second lyophobic pattern LP22 may be spaced apart from each other in the first direction (e.g., the x-axis direction or the −x-axis direction). For example, an end of the second-first lyophobic pattern LP21 disposed adjacent to the second-second lyophobic pattern LP22 may be spaced apart from an end of the second-second lyophobic pattern LP22 disposed adjacent to the second-first lyophobic pattern LP21, and another end of the second-first lyophobic pattern LP21 disposed adjacent to the second-second lyophobic pattern LP22 may be spaced apart from another end of the second-second lyophobic pattern LP22 disposed adjacent to the second-first lyophobic pattern LP21. For example, the second lyophobic pattern LP2 may partially surround the second opening OP2 in a plan view.

Each of the third-first lyophobic pattern LP31 and the third-second lyophobic pattern LP32 may surround a portion of the third opening OP3 in a plan view. For example, referring to FIG. 3, in a plan view, the third-first lyophobic pattern LP31 may surround a left side of the third opening OP3, and the third-second lyophobic pattern LP32 may surround a right side of the third opening OP3. The third-first lyophobic pattern LP31 and the third-second lyophobic pattern LP32 may be spaced apart from each other. For example, an end of the third-first lyophobic pattern LP31 disposed adjacent to the third-second lyophobic pattern LP32 may be spaced apart from an end of the third-second lyophobic pattern LP32 disposed adjacent to the third-first lyophobic pattern LP31, and another end of the third-first lyophobic pattern LP31 disposed adjacent to the third-second lyophobic pattern LP32 may be spaced apart from another end of the third-second lyophobic pattern LP32 disposed adjacent to the third-first lyophobic pattern LP31. For example, the third lyophobic pattern LP3 may partially surround the third opening OP3 in a plan view.

FIG. 4 is a schematic cross-sectional view illustrating a cross-section of the display apparatus 1 taken along line I-I′ of FIG. 3. Referring to FIG. 4, the display apparatus 1 according to an embodiment may include a substrate 100. The substrate 100 may include various materials that are flexible or bendable. For example, the substrate 100 may include a glass, a metal, a polymer resin, or the like. The substrate 100 may include a polymer resin including polyethersulfone, polyacrylate, polyetherimide, polyethylene naphthalate, polyethylene terephthalate, polyphenylene sulfide, polyarylate, polyimide, polycarbonate, cellulose acetate propionate, the like, or a combination thereof. However, the substrate 100 may be variously modified such as having a multi-layered structure including two layers including the polymer resin and a barrier layer interposed between the two layers and including an inorganic material (e.g., silicon oxide (SiOₓ), silicon nitride (SiNₓ), or silicon oxynitride (SiOₓN_{y})).

A display element included in the pixel PX and a pixel circuit PC electrically connected to the display element may be disposed on the substrate 100. FIG. 4 illustrates that the pixel PX includes an organic light emitting diode OLED as a display element. For example, the organic light emitting diode OLED may be a first organic light emitting diode OLED1, a second organic light emitting diode OLED2, and/or a third organic light emitting diode OLED3. For example, the first pixel PX1 may include a first organic light emitting diode OLED1, the second pixel PX2 may include a second organic light emitting diode OLED2, and the third pixel PX3 may include a third organic light emitting diode OLED3.

A pixel circuit PC may be disposed on the substrate 100. Structures of the pixel circuits PC of the pixels PX may the same as each other, and one pixel circuit PC will be described. The pixel circuit PC may include multiple thin film transistors TFT and a storage capacitor Cst. For convenience of illustration, FIG. 4 illustrates one thin film transistor TFT, and the thin film transistor TFT may correspond to the first transistor (see, e.g., T1 of FIG. 2) described above.

A buffer layer 201 including an inorganic material such as silicon oxide (SiOₓ), silicon nitride (SiNₓ), silicon oxynitride (SiOₓN_{y}), the like, or a combination thereof may be interposed between the thin film transistor TFT and the substrate 100. The buffer layer 201 may increase a smoothness of an upper surface of the substrate 100 or prevent or minimize a penetration of impurities into a semiconductor layer Act of the thin film transistor TFT from the substrate 100 or the like.

Referring to FIG. 4, the thin film transistor TFT may include a semiconductor layer Act including amorphous silicon, polycrystalline silicon, an organic semiconductor material, an oxide semiconductor material, or the like. The thin film transistor TFT may include a gate electrode GE, a source electrode SE, and/or a drain electrode DE. The gate electrode GE may include various conductive materials and may have various layered structures, for example, may include a Mo layer and an Al layer. In another embodiment, the gate electrode GE may include a TiNₓ layer, an Al layer, and/or a Ti layer. The source electrode SE and the drain electrode DE may include various conductive materials and may have various layered structures, for example, may include a Ti layer, an Al layer, and/or a Cu layer.

In order to secure an insulation between the semiconductor layer Act and the gate electrode GE, a gate insulating layer 203 including an inorganic material such as silicon oxide (SiOₓ), silicon nitride (SiNₓ), silicon oxynitride (SiOₓN_{y}), the like, or a combination thereof may be interposed between the semiconductor layer Act and the gate electrode GE. FIG. 4 illustrates that the gate insulating layer 203 has a shape corresponding to a surface (e.g., an entire surface) of the substrate 100 and has a structure in which contact holes are formed in a portion, however, the disclosure is not limited thereto. In another embodiment, the gate insulating layer 203 and the gate electrode GE may be patterned in a same shape.

A first interlayer insulating layer 205 including an inorganic material such as silicon oxide (SiOₓ), silicon nitride (SiNₓ), silicon oxynitride (SiOₓN_{y}), the like, or a combination thereof may be disposed on the gate electrode GE. The first interlayer insulating layer 205 may have a single-layer or multi-layered structure including the above material. The first interlayer insulating layer 205 may be formed through chemical vapor deposition (CVD), atomic layer deposition (ALD), or the like. This may also apply to the following embodiments and modifications of the following embodiments.

The storage capacitor Cst may include a first capacitor electrode CE1 and a second capacitor electrode CE2 overlapping each other with the first interlayer insulating layer 205 interposed between the first capacitor electrode CE1 and the second capacitor electrode CE2 in a plan view. The storage capacitor Cst may overlap the thin film transistor TFT in a plan view. FIG. 4 illustrates that the gate electrode GE of the thin film transistor TFT is the first capacitor electrode CE1 of the storage capacitor Cst, however, the disclosure is not limited thereto. In another embodiment, the storage capacitor Cst may not overlap the thin film transistor TFT in a plan view. The second capacitor electrode CE2 of the storage capacitor Cst may include a conductive material including molybdenum (Mo), aluminum (Al), copper (Cu), titanium (Ti), the like, or an alloy thereof and may have a single-layer or multi-layered structure including the above material.

A second interlayer insulating layer 207 including an inorganic material such as silicon oxide (SiOₓ), silicon nitride (SiNy), silicon oxynitride (SiOₓN_{y}), the like, or a combination thereof may be disposed on the second capacitor electrode CE2 of the storage capacitor Cst. The second interlayer insulating layer 207 may have a single-layer or multiple-layers structure including the above material.

The source electrode SE and the drain electrode DE may be disposed on the second interlayer insulating layer 207. The source electrode SE and the drain electrode DE may include a material having high conductivity. The source electrode SE and the drain electrode DE may include a conductive material including molybdenum (Mo), aluminum (Al), copper (Cu), titanium (Ti), the like, or an alloy thereof and may have a single-layer or multi-layered structure including the above material. For example, the source electrode SE and the drain electrode DE may have a multi-layered structure of Ti/Al/Ti.

However, the disclosure is not limited thereto. In another embodiment, the thin film transistor TFT may include only one of the source electrode SE and the drain electrode DE or may not include both of the source electrode SE and the drain electrode DE. For example, a thin film transistor TFT may not include the drain electrode DE, another thin film transistor TFT electrically connected to the thin film transistor TFT may not include the source electrode SE, and the semiconductor layers Act of the two thin film transistors (e.g., the thin film transistor TFT and the another thin film transistor TFT) may be electrically connected to each other. A connection structure may provide a same effect as an embodiment where a thin film transistor TFT also includes the source electrode SE, another thin film transistor TFT also includes the drain electrode DE, and the source electrode SE of the thin film transistor TFT is connected to the drain electrode DE of the other thin film transistor TFT.

Referring to FIG. 4, a planarization layer 208 may cover the thin film transistor TFT and the storage capacitor Cst. The planarization layer 208 may include an organic insulating material. For example, the planarization layer 208 may include a photoresist, benzocyclobutene (BCB), polyimide, hexamethyldisiloxane (HMDSO), polymethylmethacrylate (PMMA), polystyrene (PS), a polymer derivative having a phenolic group, an acrylic polymer, an imide-based polymer, an aryl ether-based polymer, an amide-based polymer, a fluorine-based polymer, a p-xylene-based polymer, a vinyl alcohol-based polymer, the like, or any mixture thereof. Although not illustrated in FIG. 4, a third interlayer insulating layer may be further disposed under the planarization layer 208. The third interlayer insulating layer may include an inorganic insulating material such as silicon oxide (SiOₓ), silicon nitride (SiNₓ), silicon oxynitride (SiOₓN_{y}), the like, or a combination thereof.

The first organic light emitting diode OLED1, the second organic light emitting diode OLED2, and the third organic light emitting diode OLED3 may be spaced apart from each other on the planarization layer 208 in the first direction (e.g., the x-axis direction or the −x-axis direction). For example, the first organic light emitting diode OLED1 and the second organic light emitting diode OLED2 disposed adjacent to each other may be arranged in the first direction (e.g., the x-axis direction or the −x-axis direction) on the planarization layer 208, and the third organic light emitting diode OLED3 may be disposed adjacent to the second organic light emitting diode OLED2 in the first direction (e.g., the x-axis direction or the −x-axis direction) on the planarization layer 208. For example, the third organic light emitting diode OLED3 may be located in an opposite direction to the first organic light emitting diode OLED1 with the second organic light emitting diode OLED2 interposed between the first organic light emitting diode OLED1 and the third organic light emitting diode OLED3 on the planarization layer 208.

The first organic light emitting diode OLED1, the second organic light emitting diode OLED2, and the third organic light emitting diode OLED3 may respectively emit light of different colors. For example, the first organic light emitting diode OLED1 may emit red light, the second organic light emitting diode OLED2 may emit green light, and the third organic light emitting diode OLED3 may emit blue light. The first organic light emitting diode OLED1 may include a first pixel electrode 211, a first emission layer 221, and an opposite electrode 230. The second organic light emitting diode OLED2 may include a second pixel electrode 212, a second emission layer 222, and an opposite electrode 230, and the third organic light emitting diode OLED3 may include a third pixel electrode 213, a third emission layer 223, and an opposite electrode 230. The opposite electrode 230 may be integrally provided on an area (e.g., an entire area) of the display apparatus 1 and accordingly may be commonly provided in multiple organic light emitting diodes OLED.

The first pixel electrode 211, the second pixel electrode 212, and the third pixel electrode 213 may be spaced apart from each other on the planarization layer 208 in the first direction (e.g., the x-axis direction or the −x-axis direction). For example, the second pixel electrode 212 may be arranged adjacent to the first pixel electrode 211 in the first direction (e.g., the x-axis direction or the −x-axis direction) on the planarization layer 208. The third pixel electrode 213 may be disposed adjacent to the second pixel electrode 212 in the first direction (e.g., the x-axis direction) on the planarization layer 208. For example, the third pixel electrode 213 may be located in an opposite direction to the first pixel electrode 211 with the second pixel electrode 212 interposed between the first pixel electrode 211 and the third pixel electrode 213 on the planarization layer 208. The first pixel electrode 211, the second pixel electrode 212, and the third pixel electrode 213 may include a transparent conductive layer formed of a transparent conductive oxide such as ITO, In₂O₃, IZO, the like, or a combination thereof and a reflective layer formed of a metal such as Al, Ag, the like, or an alloy thereof. For example, the first pixel electrode 211, the second pixel electrode 212, and the third pixel electrode 213 may have a three-layered structure of ITO/Ag/ITO.

Referring to FIG. 4, the first pixel electrode 211, the second pixel electrode 212, and the third pixel electrode 213 may be electrically connected to the thin film transistor TFT by contacting one of the source electrode SE and the drain electrode DE. Each of the first pixel electrode 211, the second pixel electrode 212, and the third pixel electrode 213 may contact one of the source electrode SE and the drain electrode DE through a contact hole formed in the planarization layer 208.

A pixel definition layer 215 may be disposed on the planarization layer 208. As described above, the pixel definition layer 215 may define a first opening OP1, a second opening OP2, and a third opening OP3. The pixel definition layer 215 may include a first inner surface IS1, a second inner surface IS2, and a third inner surface IS3. The first inner surface IS1 may define the first opening OP1, the second inner surface IS2 may define the second opening OP2, and the third inner surface IS3 may define the third opening OP3. The first opening OP1 may correspond to the first pixel PX1, the second opening OP2 may correspond to the second pixel PX2, and the third opening OP3 may correspond to the third pixel PX3. The first opening OP1 may expose a portion (e.g., a center portion) of the first pixel electrode 211 of the first organic light emitting diode OLED1, the second opening OP2 may expose a portion (e.g., a center portion) of the second pixel electrode 212 of the second organic light emitting diode OLED2, and the third opening OP3 may expose a portion (e.g., a center portion) of the third pixel electrode 213 of the third organic light emitting diode OLED3. For example, the pixel definition layer 215 may define the first, second, or third pixel (also, referred to as a pixel) PX1, PX2, or PX3 by including the first, second, or third inner surface (also, referred to as an inner surface) IS1, IS2, or IS3 defining the first, second, or third opening (also, referred to as an opening) OP1, OP2, or OP3 corresponding to the pixel PX1, PX2, or PX3, for example, the opening OP1, OP2, or OP3 through which at least a portion (e.g., a center portion) of first, second, or third pixel electrode (also, referred to as a pixel electrode) 211, 212, or 213 is exposed.

The first opening OP1, the second opening OP2, and the third opening OP3 may be an area where a portion of the pixel definition layer 215 has been removed. Referring to FIG. 4, each of the first inner surface IS1 of the first opening OP1, the second inner surface IS2 of the second opening OP2, and the third inner surface IS3 of the third opening OP3 may have an inclined structure. Each of the first inner surface IS1 defining the first opening OP1, the second inner surface IS2 defining the second opening OP2, and the third inner surface IS3 defining the third opening OP3 may include a forward-tapered inclined surface. That the inner surface IS1, IS2, or IS3 of the opening OP1, OP2, or OP3 includes a forward-tapered inclined surface may mean that a width of a portion of the opening OP1, OP2, or OP3 in an opposite direction to the direction of the substrate 100 (in the +z-axis direction) is greater than a width of a portion of the opening OP1, OP2, or OP3 in the direction of the substrate 100 (in the −z-axis direction).

In an embodiment, referring to FIG. 4, the pixel definition layer 215 may increase a distance between an edge of the first pixel electrode 211, an edge of the second pixel electrode 212, and an edge of the third pixel electrode 213 and the opposite electrode 230 on the first pixel electrode 211, the second pixel electrode 212, and the third pixel electrode 213. Accordingly, an arc or the like may be prevented from occurring at the edge of the first pixel electrode 211, the edge of the second pixel electrode 212, or the edge of the third pixel electrode 213. The pixel definition layer 215 may include, for example, an organic material such as polyimide, hexamethyldisiloxane (HMDSO), the like, or a combination thereof.

A first emission layer 221 capable of emitting red light may be disposed on the first pixel electrode 211. For example, the first emission layer 221 may be interposed between the first pixel electrode 211 and the opposite electrode 230. A second emission layer 222 capable of emitting green light may be disposed on the second pixel electrode 212, and a third emission layer 223 capable of emitting blue light may be disposed on the third pixel electrode 213. For example, the second emission layer 222 may be interposed between the second pixel electrode 212 and the opposite electrode 230, and the third emission layer 223 may be interposed between the third pixel electrode 213 and the opposite electrode 230. The first emission layer 221, the second emission layer 222, and the third emission layer 223 may include, for example, an organic material. The first emission layer 221, the second emission layer 222, and the third emission layer 223 may include a high molecular weight or low molecular weight organic material capable of emitting light of a color (e.g., a certain or selectable color such as red, green, or blue).

For example, the first emission layer 221 may include a high molecular weight or low molecular weight organic material capable of emitting red light, the second emission layer 222 may include a high molecular weight or low molecular weight organic material capable of emitting green light, and the third emission layer 223 may include a high molecular weight or low molecular weight organic material capable of emitting blue light. For example, the first emission layer 221, the second emission layer 222, and the third emission layer 223 may include a polymer material such as polyphenylene vinylene (PPV), polyfluorene, the like, or a combination thereof. The first emission layer 221, the second emission layer 222, and the third emission layer 223 may be formed by screen printing, inkjet printing, laser induced thermal imaging (LITI), or the like. However, the disclosure is not limited thereto.

In an embodiment, functional layers (not illustrated) may be disposed under and on the first emission layer 221, the second emission layer 222, and the third emission layer 223. The functional layers may include a hole injection layer (HIL), a hole transport layer (HTL), an electron transport layer (ETL), and/or an electron injection layer (EIL). The functional layers may be integral on the first pixel electrode 211, the second pixel electrode 212, and the third pixel electrode 213 or may be patterned to respectively correspond to the first pixel electrode 211, the second pixel electrode 212, and the third pixel electrode 213.

A first lyophobic pattern LP1, a second lyophobic pattern LP2, and a third lyophobic pattern LP3 may be disposed on the pixel definition layer 215. For example, the first lyophobic pattern LP1, the second lyophobic pattern LP2, and the third lyophobic pattern LP3 may cover a portion of the pixel definition layer 215. The first lyophobic pattern LP1 may cover the first inner surface IS1 defining the first opening OP1 and a portion of the upper surface of the pixel definition layer 215 disposed adjacent to the first inner surface IS1. The second lyophobic pattern LP2 may cover the second inner surface IS2 defining the second opening OP2 and a portion of the upper surface of the pixel definition layer 215 disposed adjacent to the second inner surface IS2. The third lyophobic pattern LP3 may cover the third inner surface IS3 defining the third opening OP3 and a portion of the upper surface of the pixel definition layer 215 disposed adjacent to the third inner surface IS3.

The first lyophobic pattern LP1 may cover the first inner surface IS1 defining the first opening OP1 and a portion of the upper surface of the pixel definition layer 215 disposed adjacent to the first inner surface IS1, and the first emission layer 221 may not be formed on the pixel definition layer 215 (e.g., an upper surface of the pixel definition layer 215). The second lyophobic pattern LP2 may cover the second inner surface IS2 defining the second opening OP2 and a portion of the upper surface of the pixel definition layer 215 disposed adjacent to the second inner surface IS2, and the second emission layer 222 may not be formed on the pixel definition layer 215 (e.g., an upper surface of the pixel definition layer 215). The third lyophobic pattern LP3 may cover the third inner surface IS3 defining the third opening OP3 and a portion of the upper surface of the pixel definition layer 215 disposed adjacent to the third inner surface IS3, and the third emission layer 223 may not be formed on the pixel definition layer 215 (e.g., the upper surface of the pixel definition layer 215). This will be described below.

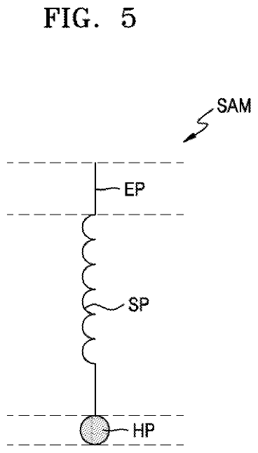

The first lyophobic pattern LP1, the second lyophobic pattern LP2, and the third lyophobic pattern LP3 may have lyophobicity (or liquid repellency). The first lyophobic pattern LP1, the second lyophobic pattern LP2, and the third lyophobic pattern LP3 may include a lyophobic material with a surface energy of equal to or less than about 20 dyne/cm. For example, each of the first lyophobic pattern LP1, the second lyophobic pattern LP2, and the third lyophobic pattern LP3 may include a self-assembled monolayer. The first lyophobic pattern LP1, the second lyophobic pattern LP2, and the third lyophobic pattern LP3 may include a same material. The self-assembled monolayer may be an organic assembly formed by adsorption of a molecular structure from a solution or a gas phase and may include a self-assembled monolayer material (see, e.g., SAM of FIG. 5).

FIG. 5 is a schematic diagram illustrating a self-assembled monolayer material. As illustrated in FIG. 5 that is a schematic diagram illustrating a self-assembled monolayer material SAM, the self-assembled monolayer material SAM may include a head portion HP, an end portion EP, and a spacer portion SP interposed between the head portion HP and the end portion EP.

The head portion HP may contact the pixel definition layer 215. The head portion HP may include a substituted or unsubstituted silyl group. Herein, “substituted or unsubstituted” may mean that at least one of the hydrogen atoms of the silyl group is substituted or not substituted by at least one of substituents such as a deuterium atom, a halogen atom, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkoxy group, a hydrocarbon ring group, an aryl group, and a heterocyclic group. For example, the alkoxy group may be a methoxy group.

The end portion EP may be located in an opposite direction to the pixel definition layer 215. For example, the end portion EP may contact a layer located on the pixel definition layer 215. The spacer portion SP may be located (or interposed) between the head portion HP and the end portion EP. The spacer portion SP and the end portion EP may include a fluorine-based functional group or a hydrocarbon-based functional group and have water repellency. For example, the spacer portion SP may include 4 to 60 CF₂ groups, and the end portion EP may include a CF₃ group. The spacer portion SP may have a (CF₂)₂₁ group. For example, each of the first lyophobic pattern LP1, the second lyophobic pattern LP2, and the third lyophobic pattern LP3 may include a self-assembled monolayer material SAM including S₁ to S₆ described below. In another embodiment, the spacer portion SP may include oxygen (O). However, the disclosure is not limited thereto.

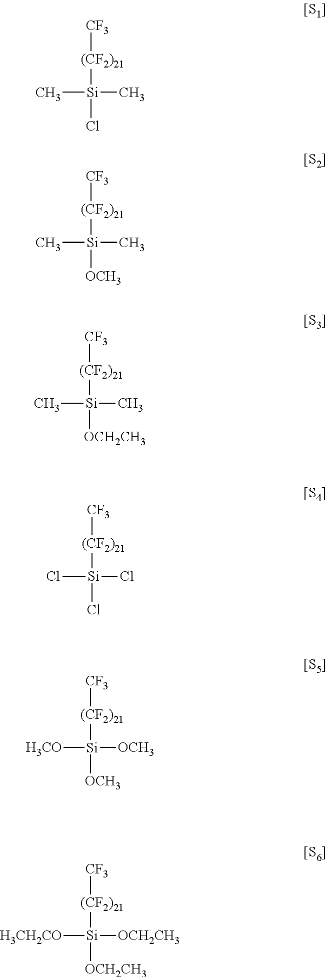

Referring to FIG. 3, the first lyophobic pattern LP1, the second lyophobic pattern LP2, and the third lyophobic pattern LP3 may be spaced apart from each other in the first direction (e.g., the x-axis direction or the −x-axis direction). The first-first lyophobic pattern LP11 and the first-second lyophobic pattern LP12 included in the first lyophobic pattern LP1 may be spaced apart from each other in the first direction (e.g., the x-axis direction or the −x-axis direction). The second-first lyophobic pattern LP21 and second-second lyophobic pattern LP22 included in the second lyophobic pattern LP2 may be spaced apart from each other, and the third-first lyophobic pattern LP31 and the third-second lyophobic pattern LP32 included in the third lyophobic pattern LP3 may be spaced apart from each other.

Referring to FIG. 4, the opposite electrode 230 may be integrally formed in the first organic light emitting diode OLED1, the second organic light emitting diode OLED2, and the third organic light emitting diode OLED3 to correspond to the first pixel electrode 211, the second pixel electrode 212, and the third pixel electrode 213. For example, the opposite electrode 230 may overlap all of the first pixel electrode 211, the second pixel electrode 212, and the third pixel electrode 213 in a plan view. The opposite electrode 230 may include a transparent conductive layer including ITO, In₂O₃, IZO, the like, or a combination thereof and may also include a semitransparent layer including a metal such as Al, Ag, the like, or an alloy thereof. For example, the opposite electrode 230 may be a semitransparent layer including Mg, Ag, the like, or an alloy thereof. The opposite electrode 230 may be integrally formed in an area (e.g., an entire area) of the display area (see, e.g., DA of FIG. 2) on the emission layers, the lyophobic patterns LP1, LP2, and LP3, and the pixel definition layer 127.

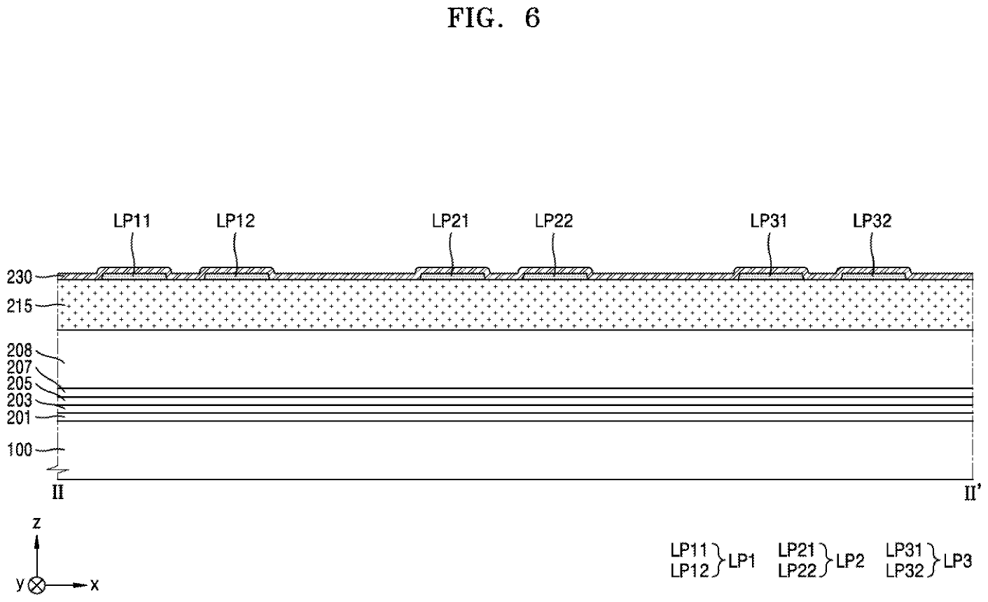

FIG. 6 is a schematic cross-sectional view illustrating a cross-section of the display apparatus 1 taken along line II-II′ of FIG. 3. Referring to FIG. 6, the upper surface of the pixel definition layer 215 between the first lyophobic pattern LP1, the second lyophobic pattern LP2, and the third lyophobic pattern LP3 may contact (e.g., directly contact) the opposite electrode 230. For example, first, second, and third lyophobic patterns (also, referred to as the lyophobic patterns) LP1, LP2, and LP3 may surround the corresponding opening (see, e.g., the first opening OP1, the second opening OP2, or the third opening OP3 of FIG. 4), the lyophobic patterns LP1, LP2, and LP3 may not have a shape corresponding to an surface (e.g., an entire surface) of the substrate 100, and the lyophobic patterns LP1, LP2, and LP3 may be spaced apart from each other in the first direction (e.g., the x-axis direction or the −x-axis direction). The upper surface of the pixel definition layer 215 between the lyophobic patterns LP1, LP2, and LP3 may contact (e.g., directly contact) the opposite electrode 230. The upper surface of the pixel definition layer 215 between the first lyophobic pattern LP1 and the second lyophobic pattern LP2 and the upper surface of the pixel definition layer 215 between the second lyophobic pattern LP2 and the third lyophobic pattern LP3 may contact (e.g., directly contact) the opposite electrode 230.

Referring to FIG. 6, the upper surface of the pixel definition layer 215 between sub lyophobic patterns (e.g., the first-first lyophobic pattern LP11 and the first-second lyophobic pattern LP12, the second-first lyophobic pattern LP21 and the second-second lyophobic pattern LP22, or the third-first lyophobic pattern LP31 and the third-second lyophobic pattern LP32) included in the first, second, or third lyophobic pattern (also, referred to as a lyophobic pattern) LP1, LP2, or LP3 surrounding the opening (see, e.g., OP1, OP2, or OP3 of FIG. 4) may contact (e.g., directly contact) the opposite electrode 230. For example, the lyophobic pattern LP1, LP2, or LP3 may partially surround the opening (see, e.g., OP1, OP2, and OP3 of FIG. 4), and the sub lyophobic patterns LP11 and LP12, LP21 and LP22, or LP31 and LP32 included in the lyophobic pattern LP1, LP2, or LP3 may be spaced apart from each other in the first direction (e.g., the x-axis direction or the −x-axis direction). The upper surface of the pixel definition layer 215 between the sub lyophobic patterns LP11 and LP12, LP21 and LP22, or LP31 and LP32 may contact (e.g., directly contact) the opposite electrode 230. The upper surface of the pixel definition layer 215 corresponding to a periphery of the opening (see, e.g., OP1, OP2, or OP3 of FIG. 4) not surrounded by the lyophobic pattern LP1, LP2, or LP3 may contact (e.g., directly contact) the opposite electrode 230. The upper surface of the pixel definition layer 215 between the first-first lyophobic pattern LP11 and the first-second lyophobic pattern LP12, the upper surface of the pixel definition layer 215 between the second-first lyophobic pattern LP21 and the second-second lyophobic pattern LP22, and the upper surface of the pixel definition layer 215 between the third-first lyophobic pattern LP31 and the third-second lyophobic pattern LP32 may contact (e.g., directly contact) the opposite electrode 230.

In an embodiment, although not illustrated, the first inner surface IS1 of a portion of the pixel definition layer 215 between the first-first lyophobic pattern LP11 and the first-second lyophobic pattern LP12 may contact (e.g., directly contact) the opposite electrode 230. The second inner surface IS2 of a portion of the pixel definition layer 215 between the second-first lyophobic pattern LP21 and the second-second lyophobic pattern LP22 may contact (e.g., directly contact) the opposite electrode 230, and the third inner surface IS3 of a portion of the pixel definition layer 215 between the third-first lyophobic pattern LP31 and the third-second lyophobic pattern LP32 may contact (e.g., directly contact) the opposite electrode 230.

FIG. 4 illustrates that the lyophobic pattern LP1, LP2, or LP3 surrounding the opening OP1, OP2, or OP3 contacts the pixel electrode 211, 212, or 213 exposed by the opening OP1, OP2, or OP3. For example, FIG. 4 illustrates that the first lyophobic pattern LP1 contacts the first pixel electrode 211, the second lyophobic pattern LP2 contacts the second pixel electrode 212, and the third lyophobic pattern LP3 contacts the third pixel electrode 213. However, the disclosure is not limited thereto. In another embodiment, the lyophobic pattern LP1, LP2, or LP3 surrounding the opening OP1, OP2, or OP3 may be spaced apart from the pixel electrode 211, 212, or 213 exposed by the opening OP1, OP2, or OP3.

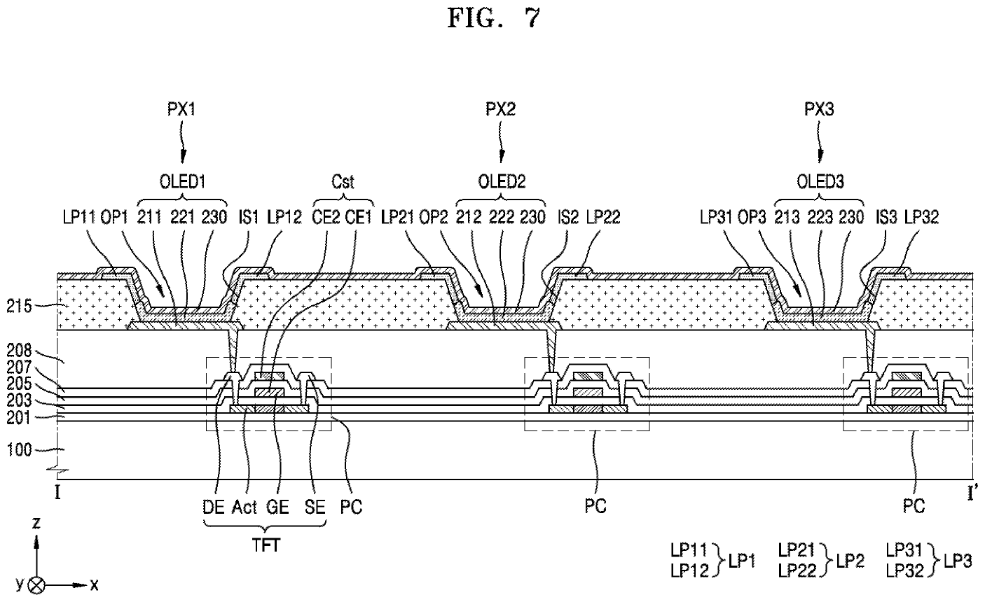

FIG. 7 is a schematic cross-sectional view illustrating a portion of a display apparatus 1 according to an embodiment. In an embodiment, referring to FIG. 7, the lyophobic pattern LP1, LP2, or LP3 surrounding the opening OP1, OP2, or OP3 may not contact the pixel electrode 211, 212, or 213 exposed by the opening OP1, OP2, or OP3. The lyophobic patterns LP1, LP2, and LP3 may not cover a portion of the inner surface IS1, IS2, or IS3 disposed adjacent to the pixel electrode 211, 212, or 213. For example, each of the lyophobic patterns LP1, LP2, and LP3 may cover only a portion of the inner surface IS1, IS2, or IS3 disposed adjacent to the upper surface of the pixel definition layer 215. Accordingly, the lyophobic pattern LP1, LP2, or LP3 surrounding the opening OP1, OP2, or OP3 may be spaced apart from the pixel electrode 211, 212, or 213 exposed by the opening OP1, OP2, or OP3.

The first lyophobic pattern LP1 may cover a portion of the upper surface of the pixel definition layer 215 disposed adjacent to the first inner surface IS1 and a portion of the first inner surface IS1 disposed adjacent to the upper surface of the pixel definition layer 215. The second lyophobic pattern LP2 may cover a portion of the upper surface of the pixel definition layer 215 disposed adjacent to the second inner surface IS2 and a portion of the second inner surface IS2 disposed adjacent to the upper surface of the pixel definition layer 215. The third lyophobic pattern LP3 may cover a portion of the upper surface of the pixel definition layer 215 disposed adjacent to the third inner surface IS3 and a portion of the third inner surface IS3 disposed adjacent to the upper surface of the pixel definition layer 215.

For example, the first lyophobic pattern LP1 may be spaced apart from the first pixel electrode 211, the second lyophobic pattern LP2 may be spaced apart from the second pixel electrode 212, and the third lyophobic pattern LP3 may be spaced apart from the third pixel electrode 213, and each of the emission layers may cover a portion of the inner surface IS1, IS2, or IS3 disposed adjacent to the pixel electrode 211, 212, or 213. The first emission layer 221 may cover a portion of the first inner surface IS1 disposed adjacent to the first pixel electrode 211. The second emission layer 222 may cover a portion of the second inner surface IS2 disposed adjacent to the second pixel electrode 212, and the third emission layer 223 may cover a portion of the third inner surface IS3 disposed adjacent to the third pixel electrode 213.

FIG. 3 illustrates that a sub lyophobic pattern LP11 and LP12, LP21 and LP22, or LP31 and LP32 included in each of the first lyophobic pattern LP1, the second lyophobic pattern LP2, and the third lyophobic pattern LP3 surrounds the left side of an opening OP1, OP2, or OP3 and another sub lyophobic pattern LP11 and LP12, LP21 and LP22, or LP31 and LP32 of the lyophobic patterns LP1, LP2, and LP3 surrounds the right side of an opening OP1, OP2, or OP3 in a plan view. However, the disclosure is not limited thereto. In another embodiment, a sub lyophobic pattern LP11 and LP12, LP21 and LP22, or LP31 and LP32 included in the first lyophobic pattern LP1, the second lyophobic pattern LP2, and the third lyophobic pattern LP3 may surround the lower side of an opening OP1, OP2, or OP3 and another sub lyophobic pattern LP11 and LP12, LP21 and LP22, or LP31 and LP32 of the lyophobic patterns LP1, LP2, and LP3 may surround the upper side of an opening OP1, OP2, or OP3 in a plan view.

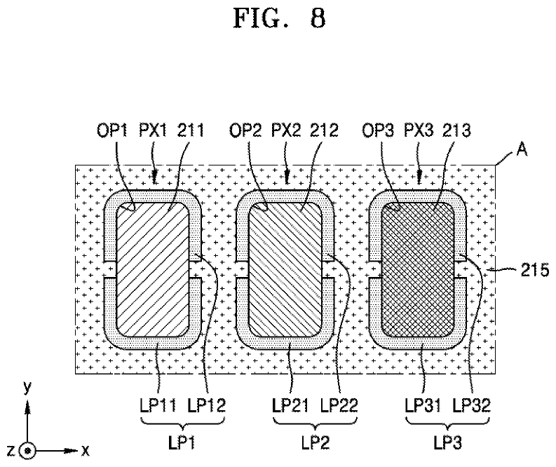

FIG. 8 is a schematic plan view illustrating a display apparatus 1 according to an embodiment. Referring to FIG. 8, the first-first lyophobic pattern LP11 may surround the lower side of the first opening OP1 and the first-second lyophobic pattern LP12 may surround the upper side of the first opening OP1 in a plan view. In a plan view, the second-first lyophobic pattern LP21 may surround the lower side of the second opening OP2 and the second-second lyophobic pattern LP22 may surround the upper side of the second opening OP2. In a plan view, the third-first lyophobic pattern LP31 may surround the lower side of the third opening OP3 and the third-second lyophobic pattern LP32 may surround the upper side of the third opening OP3.

FIGS. 3 and 8 illustrate that the first lyophobic pattern LP1, the second lyophobic pattern LP2, and the third lyophobic pattern LP3 includes two sub lyophobic patterns LP11 and LP12, LP21 and LP22, or LP31 and LP32, respectively. However, the disclosure is not limited thereto. In another embodiment, each of the first lyophobic pattern LP1, the second lyophobic pattern LP2, and the third lyophobic pattern LP3 may include at least two sub lyophobic patterns.

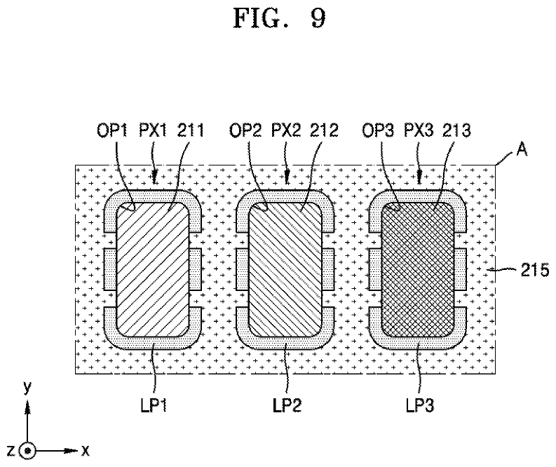

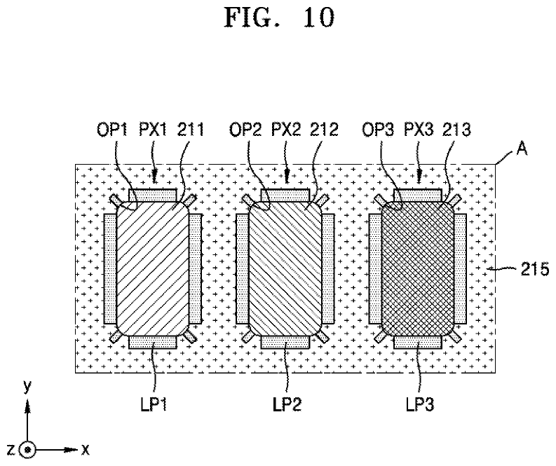

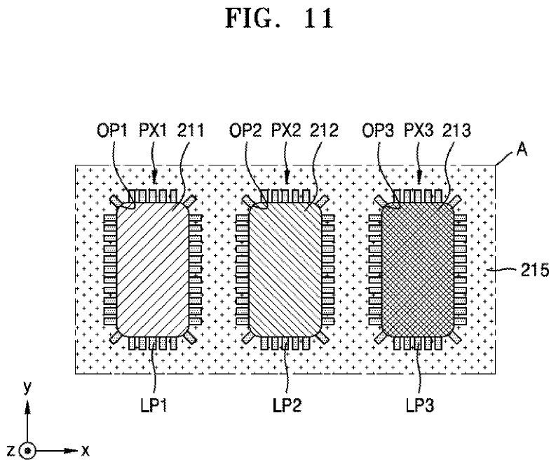

FIGS. 9 to 11 are schematic plan views illustrating a display apparatus 1 according to an embodiment. Referring to FIG. 9, each of the first lyophobic pattern LP1, the second lyophobic pattern LP2, and the third lyophobic pattern LP3 may include four sub lyophobic patterns. Referring to FIG. 10, each of the first lyophobic pattern LP1, the second lyophobic pattern LP2, and the third lyophobic pattern LP3 may include eight sub lyophobic patterns. However, the number of sub lyophobic patterns included in each of the first lyophobic pattern LP1, the second lyophobic pattern LP2, and the third lyophobic pattern LP3 may be variously modified according to a design of the display apparatus 1. In an embodiment, referring to FIG. 11, each of the first lyophobic pattern LP1, the second lyophobic pattern LP2, and the third lyophobic pattern LP3 may include multiple sub lyophobic patterns.

Because the organic light emitting diodes (see, e.g., OLED of FIG. 2) may be damaged by moisture or oxygen from an outside, an encapsulation layer (not illustrated) may cover and protect the organic light emitting diodes (see, e.g., OLED of FIG. 2). The encapsulation layer may include a first inorganic encapsulation layer, an organic encapsulation layer, and a second inorganic encapsulation layer and may cover the display area (see, e.g., DA of FIG. 2) and extend to an outside of the display area (see, e.g., DA of FIG. 2).

Although the display apparatus 1 has been described above, the disclosure is not limited thereto. A method of manufacturing the display apparatus 1 will also fall within the scope of the disclosure. Hereinafter, a method of manufacturing the display apparatus 1 will be described.

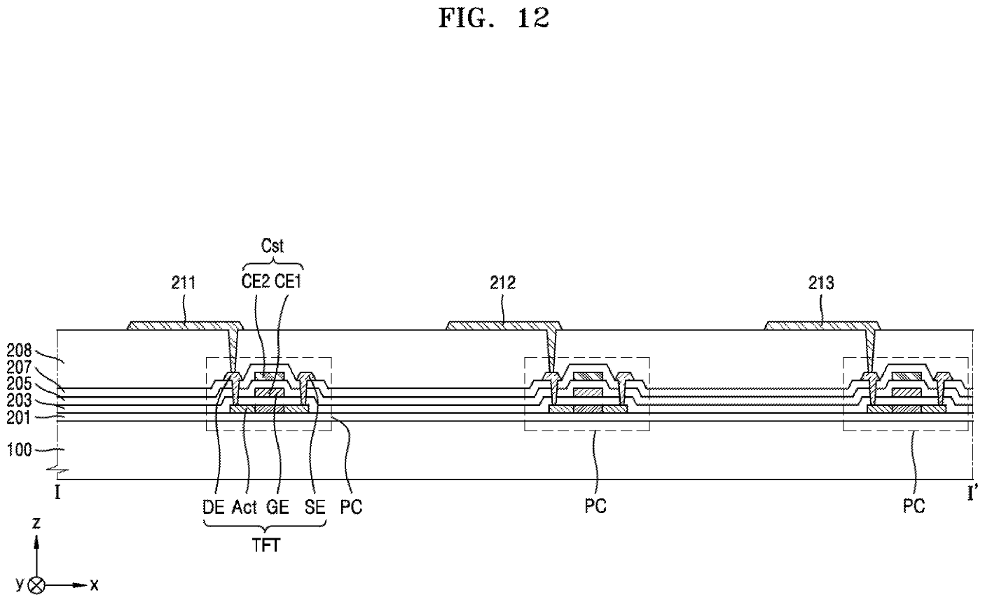

FIGS. 12 to 19 are schematic cross-sectional views illustrating a process of manufacturing the display apparatus 1 of FIG. 4. FIGS. 12 to 19 are schematic cross-sectional views illustrating a process of forming the pixel electrodes 211, 212, and 213, the pixel definition layer 215, the lyophobic patterns LP1, LP2, and LP3, the emission layers, and the opposite electrode 230 of the display apparatus (scc, e.g., 1 of FIG. 4).

Referring to FIG. 12, a first pixel electrode 211, a second pixel electrode 212, and a third pixel electrode 213 may be formed on a substrate 100. The first pixel electrode 211, the second pixel electrode 212, and the third pixel electrode 213 may be spaced apart from each other in the first direction (e.g., the x-axis direction or the −x-axis direction).

A pixel circuit PC may be formed on the substrate 100. Before the forming of the first pixel electrode 211, the second pixel electrode 212, and the third pixel electrode 213 on the substrate 100, a buffer layer 201 may be formed on the substrate 100, a semiconductor layer Act may be formed on the buffer layer 201, a gate insulating layer 203 may be formed on the semiconductor layer Act, and a gate electrode GE may be formed on the gate insulating layer 203. The gate electrode GE may be a first capacitor electrode CE1 of a storage capacitor Cst. A first interlayer insulating layer 205 may be formed on the gate electrode GE, and a second capacitor electrode CE2 may be formed on the first interlayer insulating layer 205. A second interlayer insulating layer 207 may be formed on the second capacitor electrode CE2. A source electrode SE and a drain electrode DE may be formed on the second interlayer insulating layer 207, and a planarization layer 208 may be formed on the source electrode SE and the drain electrode DE. The pixel circuit PC may be formed through a photo process or the like, and detailed descriptions thereof will be omitted.

The first pixel electrode 211, the second pixel electrode 212, and the third pixel electrode 213 may be formed on the planarization layer 208. After a contact hole is formed in the planarization layer 208 such that each of the first pixel electrode 211, the second pixel electrode 212, and the third pixel electrode 213 may contact one of the source electrode SE and the drain electrode DE, a preliminary pixel electrode layer (not illustrated) may be formed on the planarization layer 208 corresponding to a surface (e.g., an entire surface) of the substrate 100. The first pixel electrode 211, the second pixel electrode 212, and the third pixel electrode 213 may be formed by patterning the preliminary pixel electrode layer. For example, the first pixel electrode 211, the second pixel electrode 212, and the third pixel electrode 213 may be formed on the substrate 100.

The first pixel electrode 211, the second pixel electrode 212, and the third pixel electrode 213 may include a transparent conductive layer including a transparent conductive oxide such as ITO, In₂O₃, IZO, the like, or a combination thereof, and a reflective layer including a metal such as Al, Ag, the like, or an alloy thereof. For example, the first pixel electrode 211, the second pixel electrode 212, and the third pixel electrode 213 may have a three-layered structure of ITO/Ag/ITO.

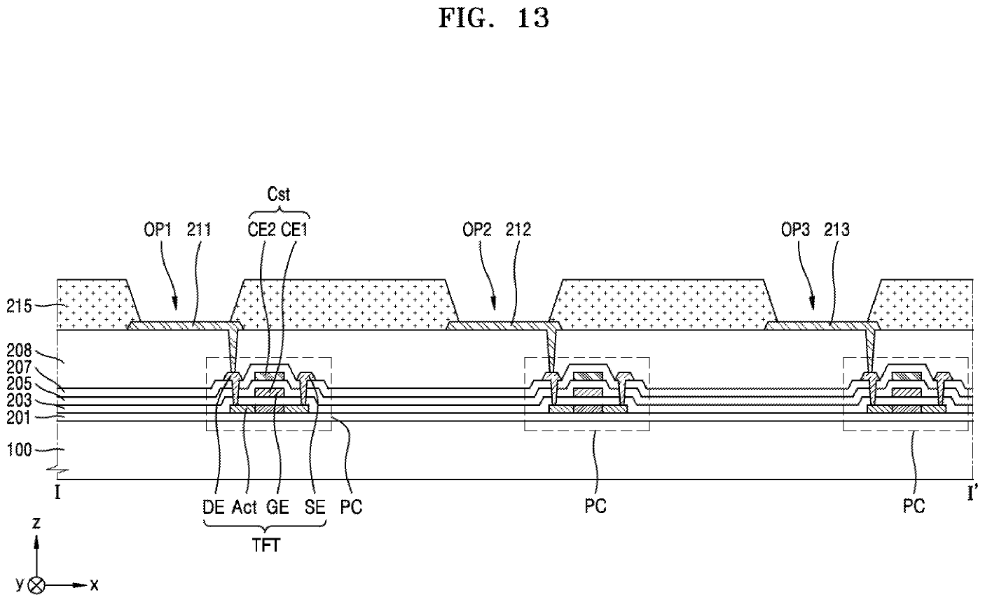

Referring to FIG. 13, a pixel definition layer 215 may be formed on the first pixel electrode 211, the second pixel electrode 212, the third pixel electrode 213, and the planarization layer 208. The pixel definition layer 215 may include a first inner surface IS1, a second inner surface IS2, and a third inner surface IS3. The first inner surface IS1 may define the first opening OP1, the second inner surface IS2 may define the second opening OP2, and the third inner surface IS3 may define the third opening OP3. The first opening OP1 may expose a portion (e.g., a center portion) of the first pixel electrode 211, the second opening OP2 may expose a portion (e.g., a center portion) of the second pixel electrode 212, and the third opening OP3 may expose a portion (e.g., a center portion) of the third pixel electrode 213. For example, the pixel definition layer 215 formed on the substrate 100 may include a first inner surface IS1 defining the first opening OP1 exposing a portion of the first pixel electrode 211, a second inner surface IS2 defining the second opening OP2 exposing a portion of the second pixel electrode 212, and a third inner surface IS3 defining the third opening OP3 exposing a portion of the third pixel electrode 213.

A preliminary pixel definition layer (not illustrated) may be formed to cover the first pixel electrode 211, the second pixel electrode 212, the third pixel electrode 213, and the planarization layer 208. The pixel definition layer 215 may be formed by patterning the preliminary pixel definition layer. For example, the pixel definition layer 215 may be formed by removing a portion of the preliminary pixel definition layer. For example, the pixel definition layer 215 may be formed on the substrate 100. The preliminary pixel definition layer and the pixel definition layer 215 may include, for example, an organic material such as polyimide, hexamethyldisiloxane (HMDSO), the like, or a combination thereof.

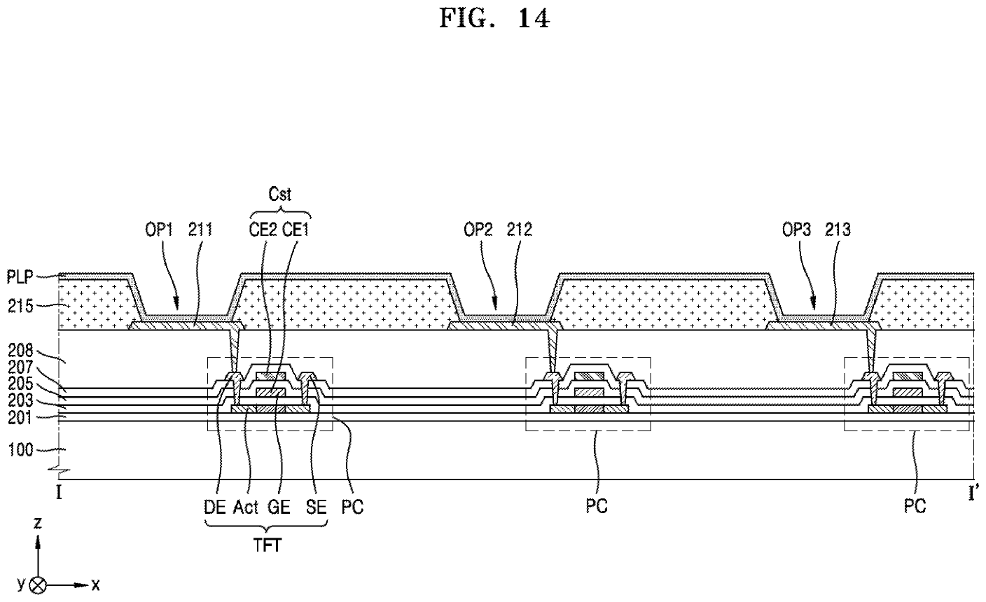

Referring to FIG. 14, a preliminary lyophobic pattern layer PLP may be formed on the pixel definition layer 215, the first pixel electrode 211, the second pixel electrode 212, and the third pixel electrode 213. The preliminary lyophobic pattern layer PLP may include a self-assembled monolayer. The preliminary lyophobic pattern layer PLP may include the self-assembled monolayer including a self-assembled monolayer material SAM. For example, the preliminary lyophobic pattern layer PLP including a lyophobic material may be formed to cover the pixel definition layer 215, the first pixel electrode 211, the second pixel electrode 212, and the third pixel electrode 213. The description of the self-assembled monolayer and the self-assembled monolayer material (see, e.g., SAM of FIG. 5) and the self-assembled monolayer and the self-assembled monolayer material SAM of the preliminary lyophobic pattern layer PLP of FIG. 14 may be the same, redundant descriptions thereof will be omitted for conciseness.

The preliminary lyophobic pattern layer PLP may be formed by depositing a self-assembled monolayer material SAM on the substrate 100 by thermal evaporation, CVD, electron-beam evaporation, or the like. For example, in a thermal evaporation process, the forming of the preliminary lyophobic pattern layer PLP may be performed in a vacuum chamber. The self-assembled monolayer material SAM may be placed on a material providing part, and the material providing part may be heated. Accordingly, the self-assembled monolayer material SAM may be heated and evaporated and the self-assembled monolayer material SAM may be deposited on the pixel definition layer 215, the first pixel electrode 211, the second pixel electrode 212, and the third pixel electrode 213.

In another embodiment, in a CVD process, the self-assembled monolayer material SAM may undergo thermal decomposition, photolysis, or oxidation-reduction reaction and the self-assembled monolayer material SAM may be deposited on the pixel definition layer 215, the first pixel electrode 211, the second pixel electrode 212, and the third pixel electrode 213. In another embodiment, in an electron-beam deposition process, the self-assembled monolayer material SAM may be heated and evaporated by an electron beam and the self-assembled monolayer material SAM may be deposited on the pixel definition layer 215, the first pixel electrode 211, the second pixel electrode 212, and the third pixel electrode 213. The preliminary lyophobic pattern layer PLP may be formed by the self-assembled monolayer material SAM deposited on the pixel definition layer 215, the first pixel electrode 211, the second pixel electrode 212, and the third pixel electrode 213.

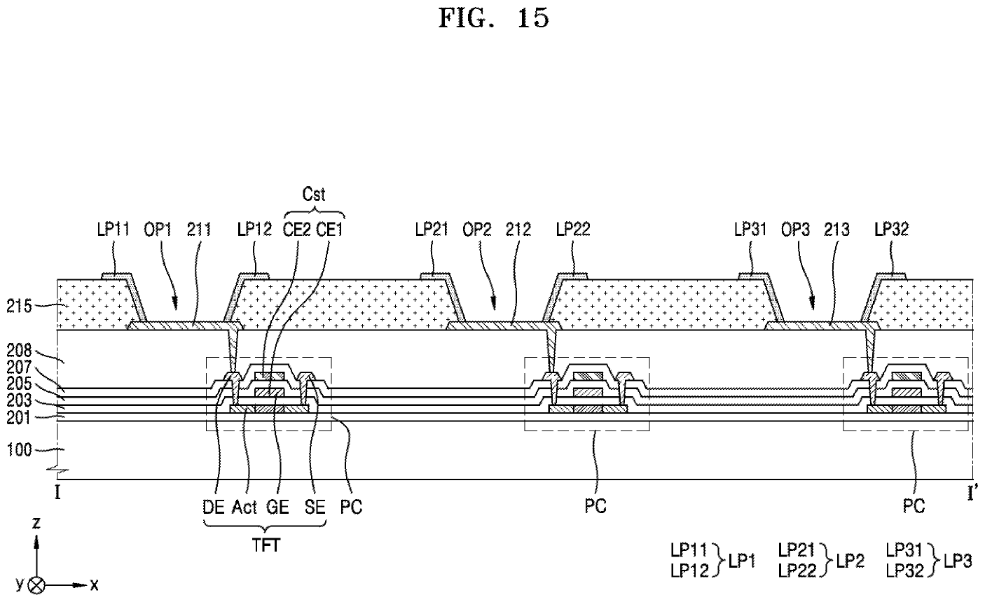

Referring to FIG. 15, a first lyophobic pattern LP1, a second lyophobic pattern LP2, and a third lyophobic pattern LP3 may be formed by removing a portion of the preliminary lyophobic pattern layer PLP. The portion of the preliminary lyophobic pattern layer PLP may be removed by UV treatment or the like. For example, in an UV treatment process, a portion of the preliminary lyophobic pattern layer PLP may be decomposed and removed by irradiating a portion of the preliminary lyophobic pattern layer PLP with UV in a wavelength band of equal to or less than about 200 nm under a vacuum condition. In another embodiment, a portion of the preliminary lyophobic pattern layer PLP may be decomposed and removed by irradiating a portion of the preliminary lyophobic pattern layer PLP with UV in a wavelength band of equal to less than about 200 nm in a nitrogen (N2) atmosphere. Another portion of the preliminary lyophobic pattern layer PLP that has not been UV-treated may remain on the substrate 100. For example, the first lyophobic pattern LP1, the second lyophobic pattern LP2, and the third lyophobic pattern LP3 may be another portion of the preliminary lyophobic pattern layer PLP that has not been UV-treated. The UV treatment for removing a portion of the preliminary lyophobic pattern layer PLP may be performed by using a mask. For example, a mask including an open area and a shielding area may be placed on the substrate 100 and UV may be irradiated to the substrate 100. A portion of the preliminary lyophobic pattern layer PLP corresponding to the open area of the mask may be removed by UV treatment, and a portion of the preliminary lyophobic pattern layer PLP corresponding to the shielding area of the mask may remain by not being UV-treated.

The first lyophobic pattern LP1, the second lyophobic pattern LP2, and the third lyophobic pattern LP3 may cover a portion of the pixel definition layer 215. The first lyophobic pattern LP1 may cover the first inner surface IS1 defining the first opening OP1 and a portion of the upper surface of the pixel definition layer 215 disposed adjacent to the first inner surface IS1. The second lyophobic pattern LP2 may cover the second inner surface IS2 defining the second opening OP2 and a portion of the upper surface of the pixel definition layer 215 disposed adjacent to the second inner surface IS2. The third lyophobic pattern LP3 may cover the third inner surface IS3 defining the third opening OP3 and a portion of the upper surface of the pixel definition layer 215 disposed adjacent to the third inner surface IS3.

The first lyophobic pattern LP1 may include a first-first lyophobic pattern LP11 and a first-second lyophobic pattern LP12, the second lyophobic pattern LP2 may include a second-first lyophobic pattern LP21 and a second-second lyophobic pattern LP22, and the third lyophobic pattern LP3 may include a third-first lyophobic pattern LP31 and a third-second lyophobic pattern LP32. Referring to FIG. 3, in a plan view, each of the first-first lyophobic pattern LP11 and first-second lyophobic pattern LP12 may surround a portion of the first opening OP1, each of the second-first lyophobic pattern LP21 and second-second lyophobic pattern LP22 may surround a portion of the second opening OP2, and each of the third-first lyophobic pattern LP31 and the third-second lyophobic pattern LP32 may surround a portion of the third opening OP3. For example, in a plan view, the first lyophobic pattern LP1 may partially surround the first opening OP1, the second lyophobic pattern LP2 may partially surround the second opening OP2, and the third lyophobic pattern LP3 may partially surround the third opening OP3.

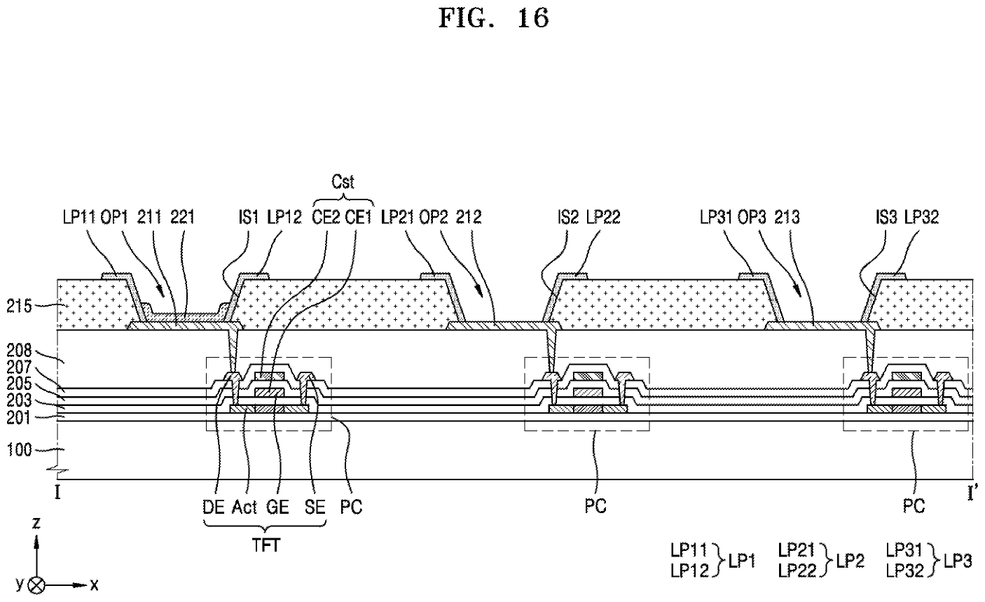

Referring to FIG. 16, a first emission layer 221 may be formed in the first opening OP1. A first emission layer forming material may be ejected to the first opening OP1 by inkjet printing or the like. The first emission layer forming material may be a solution produced by mixing an organic material included in the first emission layer 221 with a solvent. The first emission layer 221 may be formed in the first opening OP1 by removing the solvent by drying the first emission layer forming material ejected to the first opening OP1.

By considering a thickness of the first emission layer 221 finally formed in the process of the forming the first emission layer 221, a larger amount of the first emission layer forming material than an amount that may fill the first opening OP1 may be ejected to the first opening OP1. For example, the highest point of the first emission layer forming material ejected to the first opening OP1 may be higher than the upper surface of the pixel definition layer 215. For example, in case that a height of the first opening OP1 in the thickness direction (e.g., the z-axis direction or the −z-axis direction) (e.g., the thickness of the pixel definition layer 215) is about 1.2 μm, a height of the droplet of the ejected first emission layer forming material may be about 6 μm.

In general, in case that the pixel definition layer 215 has lyophilicity, a portion of the droplet of an emission layer forming material may spread widely on the upper surface of the pixel definition layer 215. For example, the emission layer forming material may overflow out of the opening OP1, OP2, or OP3. In the process of drying an emission layer forming material ejected to the opening OP1, OP2, or OP3, a portion of the droplet of the emission layer forming material may remain on the upper surface of the pixel definition layer 215. Accordingly, the thickness of a formed emission layer may not be uniform.

However, according to an embodiment, the upper surface of the pixel definition layer 215 disposed adjacent to the first inner surface IS1 defining the first opening OP1 may be covered with the first lyophobic pattern LP1, and the first lyophobic pattern LP1 may have lyophobicity. A portion of the droplet of the ejected first emission layer forming material located on the first lyophobic pattern LP1 may not spread widely on the upper surface of the pixel definition layer 215. For example, the first emission layer forming material may not overflow out of the first opening OP1 or an amount of an overflow out of the first opening OP1 may be minimized. In the process of drying the first emission layer forming material ejected to the first opening OP1, a point where the first lyophobic pattern LP1 with lyophobicity and the first pixel electrode 211 with lyophilicity contact each other may be a pinning point. Accordingly, in the process of drying the first emission layer forming material ejected to the first opening OP1, a droplet of the first emission layer forming material may not remain on the upper surface of the pixel definition layer 215. The thickness of the formed first emission layer 221 may be uniform.

The first emission layer forming material and the first emission layer 221 may include a high molecular weight or low molecular weight organic material capable of emitting red light. For example, the first emission layer forming material and the first emission layer 221 may include a polymer material such as polyphenylene vinylene (PPV), polyfluorene, the like, or a combination thereof.

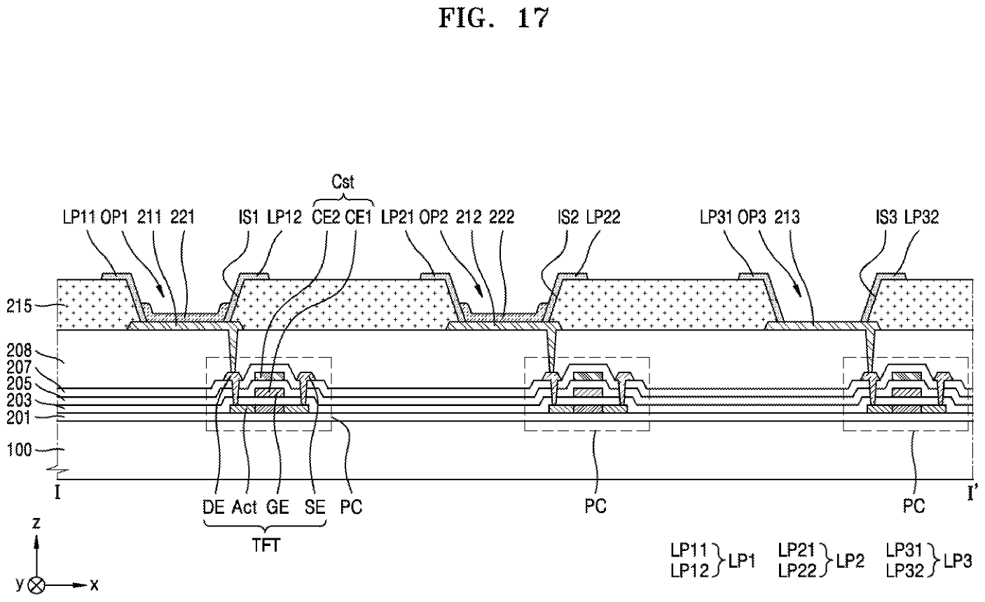

Referring to FIG. 17, a second emission layer 222 may be formed in the second opening OP2. A second emission layer forming material may be ejected to the second opening OP2 by inkjet printing or the like. The second emission layer 222 forming material may be a solution produced by mixing an organic material constituting the second emission layer 222 with a solvent. The second emission layer 222 may be formed in the second opening OP2 by removing the solvent by drying the second emission layer forming material ejected to the second opening OP2.

By considering a thickness of the second emission layer 222 finally formed in the process of the forming the second emission layer 222, a larger amount of the second emission layer forming material than an amount that may fill the second opening OP2 may be ejected to the second opening OP2. For example, the highest point of the second emission layer forming material ejected to the second opening OP2 may be higher than the upper surface of the pixel definition layer 215. For example, in case that a height of the second opening OP2 in the thickness direction (e.g., the z-axis direction or the −z-axis direction) (e.g., the thickness of the pixel definition layer 215) is about 1.2 μm, a height of the droplet of the ejected second emission layer forming material may be about 6 μm.

Because the effect occurring in case that the upper surface of the pixel definition layer 215 disposed adjacent to the first inner surface IS1 defining the first opening OP1 is covered with the first lyophobic pattern LP1 occurs also in case that the upper surface of the pixel definition layer 215 disposed adjacent to the second inner surface IS2 defining the second opening OP2 is covered with the second lyophobic pattern LP2, redundant descriptions thereof will be omitted. The second emission layer forming material may not overflow out of the second opening OP2 or the amount of an overflow of the second opening OP2 may be minimized. In the process of drying the second emission layer forming material ejected to the second opening OP2, a point where the second lyophobic pattern LP2 with lyophobicity and the second pixel electrode 212 with lyophilicity contact each other may be a pinning point. Accordingly, in the process of drying the second emission layer forming material ejected to the second opening OP2, the droplet of the second emission layer forming material may not remain on the upper surface of the pixel definition layer 215. The thickness of the formed second emission layer 222 may be uniform.

The second emission layer forming material and the second emission layer 222 may include a high molecular weight or low molecular weight organic material capable of emitting green light. For example, the second emission layer forming material and the second emission layer 222 may include a polymer material such as polyphenylene vinylene (PPV), polyfluorene, the like, or a combination thereof.

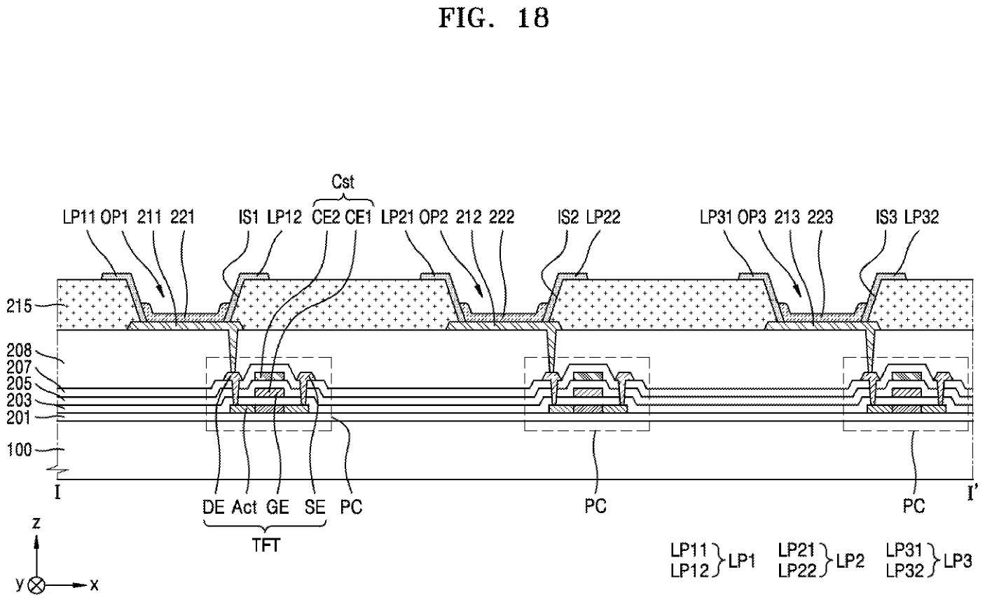

Referring to FIG. 18, a third emission layer 223 may be formed in the third opening OP3. A third emission layer forming material may be ejected to the third opening OP3 by inkjet printing or the like. The third emission layer forming material may be a solution produced by mixing an organic material constituting the third emission layer 223 with a solvent. The third emission layer 223 may be formed in the third opening OP3 by removing the solvent by drying the third emission layer forming material ejected to the third opening OP3.

By considering a thickness of the third emission layer 223 finally formed in the process of the forming the third emission layer 223, a larger amount of the third emission layer forming material than an amount that may fill the third opening OP3 may be ejected to the third opening OP3. For example, the highest point of the third emission layer forming material ejected to the third opening OP3 may be higher than the upper surface of the pixel definition layer 215. For example, in case that the height of the third opening OP3 in the thickness direction (e.g., the z-axis direction or the −z-axis direction) (e.g., the thickness of the pixel definition layer 215) is about 1.2 μm, the height of the droplet of the ejected third emission layer forming material may be about 6 μm.

Because the effect occurring in case that the upper surface of the pixel definition layer 215 disposed adjacent to the first inner surface IS1 defining the first opening OP1 is covered with the first lyophobic pattern LP1 occurs also in case that the upper surface of the pixel definition layer 215 disposed adjacent to the third inner surface IS3 defining the third opening OP3 is covered with the third lyophobic pattern LP3, redundant descriptions thereof will be omitted for conciseness. The third emission layer forming material may not overflow out of the third opening OP3 or the amount of an overflow out of the third opening OP3 may be minimized. In the process of drying the third emission layer forming material ejected to the third opening OP3, a point where the third lyophobic pattern LP3 with lyophobicity and the third pixel electrode 213 with lyophilicity contact each other may be a pinning point. Accordingly, in the process of drying the third emission layer forming material ejected to the third opening OP3, the droplet of the third emission layer forming material may not remain on the upper surface of the pixel definition layer 215. The thickness of the formed third emission layer 223 may be uniform.

The third emission layer forming material and the third emission layer 223 may include a high molecular weight or low molecular weight organic material capable of emitting green light. For example, the third emission layer forming material and the third emission layer 223 may include a polymer material such as polyphenylene vinylene (PPV), polyfluorene, the like, or a combination thereof.

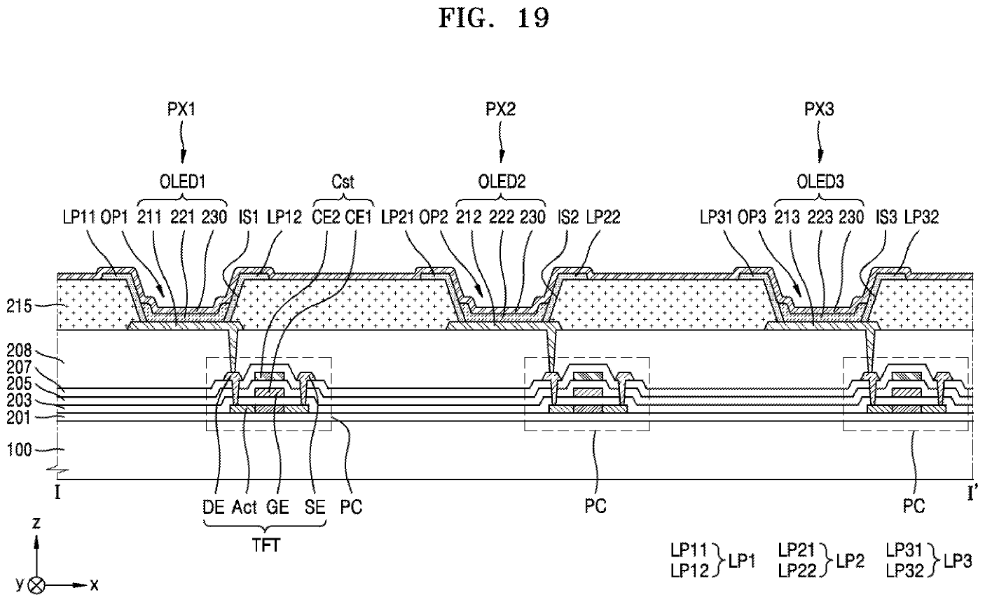

Referring to FIG. 19, an opposite electrode 230 may be formed on the first pixel electrode 211, the second pixel electrode 212, and the third pixel electrode 213. The opposite electrode 230 may be integrally formed corresponding to the first pixel electrode 211, the second pixel electrode 212, and the third pixel electrode 213. Accordingly, the opposite electrode 230 may overlap all of the first pixel electrode 211, the second pixel electrode 212, and the third pixel electrode 213 in a plan view. The opposite electrode 230 may include a transparent conductive layer including ITO, In₂O₃, IZO, or the like and may also include a semitransparent layer including a metal such as Al, Ag, the like, or an alloy thereof. For example, the opposite electrode 230 may be a semitransparent layer including Mg or Ag.

In general, it may not readily form a layer including an organic material or a metal on a layer including a material with low surface energy. Even in case that a layer including an organic material or a metal material is formed on a layer including a material with low surface energy, an adhesive force between the layers may be low. Because the lyophobic pattern LP1, LP2, or LP3 includes a lyophobic material having lyophobicity and low surface energy, the adhesive force between the lyophobic pattern LP1, LP2, or LP3 and the opposite electrode 230 may be low. In case that the entire upper surface of the pixel definition layer 215 is covered by the lyophobic pattern, the adhesive force between the pixel definition layer 215 and the opposite electrode 230 may be low.

However, in an embodiment of the display apparatus manufacturing method, the lyophobic patterns LP1, LP2, and LP3 may be spaced apart from each other in the first direction (e.g., the x-axis direction or the −x-axis direction). The first lyophobic pattern LP1, the second lyophobic pattern LP2, and the third lyophobic pattern LP3 may be spaced apart from each other in the first direction (e.g., the x-axis direction or the −x-axis direction). Accordingly, the upper surface of the pixel definition layer 215 between the lyophobic patterns LP1, LP2, and LP3 may contact (e.g., directly contact) the opposite electrode 230. The upper surface of the pixel definition layer 215 between the first lyophobic pattern LP1 and the second lyophobic pattern LP2 and the upper surface of the pixel definition layer 215 between the second lyophobic pattern LP2 and the third lyophobic pattern LP3 may contact (e.g., directly contact) the opposite electrode 230. Thus, the adhesive force between the pixel definition layer 215 and the opposite electrode 230 may be improved.

In an embodiment of the display apparatus manufacturing method, the sub lyophobic patterns LP11 and LP12, LP21 and LP22, or LP31 and LP32 included in the lyophobic pattern LP1, LP2, or LP3 respectively surrounding the opening OP1, OP2, or OP3 may be spaced apart from each other in the first direction (e.g., the x-axis direction or the −x-axis direction). The first lyophobic pattern LP1 surrounding the first opening OP1 may include a first-first lyophobic pattern LP11 and a first-second lyophobic pattern LP12 as sub lyophobic patterns LP11 and LP12, LP21 and LP22, or LP31 and LP32, and the first-first lyophobic pattern LP11 and the first-second lyophobic pattern LP12 may be spaced apart from each other in the first direction (e.g., the x-axis direction or the −x-axis direction). Accordingly, the upper surface of the pixel definition layer 215 between the sub lyophobic patterns LP11 and LP12, LP21 and LP22, or LP31 and LP32 may contact (e.g., directly contact) the opposite electrode 230. Referring to FIG. 6, in the display apparatus 1 manufactured by a manufacturing method, the upper surface of the pixel definition layer 215 between the first-first lyophobic pattern LP11 and the first-second lyophobic pattern LP12, the upper surface of the pixel definition layer 215 between the second-first lyophobic pattern LP21 and the second-second lyophobic pattern LP22, and the upper surface of the pixel definition layer 215 between the third-first lyophobic pattern LP31 and the third-second lyophobic pattern LP32 may contact (e.g., directly contact) the opposite electrode 230. The adhesive force between the portion of the pixel definition layer 215 disposed adjacent to the opening OP1, OP2, or OP3 and the opposite electrode 230 may be remarkably improved. Accordingly, a defect occurrence possibility in a manufacturing process may be reduced.

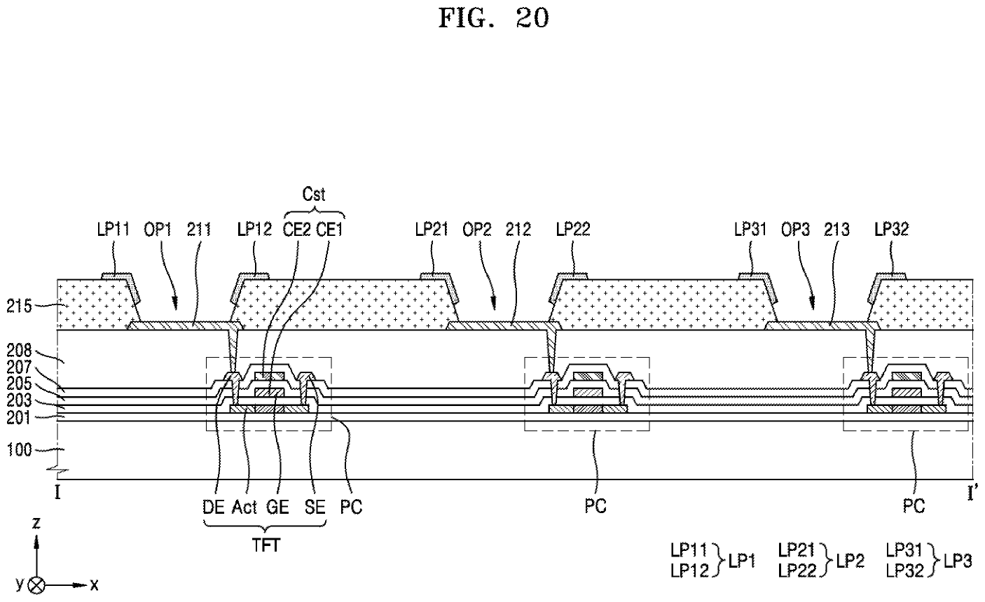

FIG. 20 is a schematic cross-sectional view illustrating a display apparatus manufacturing method (or a method of manufacturing the display apparatus) according to an embodiment. FIG. 20 is a schematic cross-sectional view illustrating a process of forming the lyophobic patterns LP1, LP2, and LP3 of the display apparatus 1 of FIG. 7. The display apparatus manufacturing method according to an embodiment of FIG. 20 may correspond to a partially modified embodiment of the display apparatus manufacturing method of FIGS. 12 to 19, differences from the display apparatus manufacturing method of FIGS. 12 to 19 will be described. In FIG. 20, like reference numerals as those in FIGS. 12 and 19 will denote like members, and redundant descriptions thereof will be omitted for conciseness.

In the display apparatus manufacturing method according to an embodiment, the first pixel electrode 211, the second pixel electrode 212, and the third pixel electrode 213 may be formed on a substrate 100, the pixel definition layer 215 may be formed on the first pixel electrode 211, the second pixel electrode 212, the third pixel electrode 213, and the planarization layer 208, and the preliminary lyophobic pattern layer PLP may be formed on the pixel definition layer 215, the first pixel electrode 211, the second pixel electrode 212, and the third pixel electrode 213. In the display apparatus manufacturing method according to an embodiment, the first emission layer 221 may be formed in the first opening OP1, the second emission layer 222 may be formed in the second opening OP2, the third emission layer 223 may be formed in the third opening OP3, and the opposite electrode 230 may be formed on the first pixel electrode 211, the second pixel electrode 212, and the third pixel electrode 213. The processes in the display apparatus manufacturing method of FIGS. 12 to 14 and the processes in the display apparatus manufacturing method of FIGS. 16 to 19 may be the same, redundant descriptions thereof will be omitted.

However, in an embodiment of the display apparatus manufacturing method, referring to FIG. 20, in case that the first lyophobic pattern LP1, the second lyophobic pattern LP2, and the third lyophobic pattern LP3 are formed by removing a portion of the preliminary lyophobic pattern layer PLP, a portion of the preliminary lyophobic pattern layer PLP may be removed such that each lyophobic pattern does not cover a portion of the inner surface IS1, IS2, or IS3 disposed adjacent to the pixel electrode. For example, each of the lyophobic patterns LP1, LP2, and LP3 may cover only a portion of the inner surface IS1, IS2, or IS3 disposed adjacent to the upper surface of the pixel definition layer 215.

The first lyophobic pattern LP1 may cover a portion of the upper surface of the pixel definition layer 215 disposed adjacent to the first inner surface IS1 and a portion of the first inner surface IS1 disposed adjacent to the upper surface of the pixel definition layer 215. The second lyophobic pattern LP2 may cover a portion of the upper surface of the pixel definition layer 215 disposed adjacent to the second inner surface IS2 and a portion of the second inner surface IS2 disposed adjacent to the upper surface of the pixel definition layer 215. The third lyophobic pattern LP3 may cover a portion of the upper surface of the pixel definition layer 215 disposed adjacent to the third inner surface IS3 and a portion of the third inner surface IS3 disposed adjacent to the upper surface of the pixel definition layer 215. For example, the first lyophobic pattern LP1 may be formed to be spaced apart from the first pixel electrode 211, the second lyophobic pattern LP2 may be formed to be spaced apart from the second pixel electrode 212, and the third lyophobic pattern LP3 may be formed to be spaced apart from the third pixel electrode 213.

In the process of drying the first emission layer forming material ejected to the first opening OP1, a point where the first lyophobic pattern LP1 with lyophobicity and the pixel definition layer 215 with lyophilicity contact each other may be a pinning point. In the process of drying the second emission layer forming material ejected to the second opening OP2, a point where the second lyophobic pattern LP2 with lyophobicity and the pixel definition layer 215 with lyophilicity contact each other may be a pinning point. In the process of drying the third emission layer forming material ejected to the third opening OP3, a point where the third lyophobic pattern LP3 with lyophobicity and the pixel definition layer 215 with lyophilicity contact each other may be a pinning point.

Accordingly, in the display apparatus manufacturing method according to an embodiment, the first emission layer 211 forming material may not overflow out of the first opening OP1 or an amount of an overflow out of the first opening OP1 may be minimized. The second emission layer 212 forming material may not overflow out of the second opening OP2 or an amount of an overflow out of the second opening OP2 may be minimized, and the third emission layer 213 forming material may not overflow out of the third opening OP3 or an amount of an overflow out of the third opening OP3 may be minimized. The droplet of the first emission layer 211 forming material, the droplet of the second emission layer 212 forming material, and the droplet of the third emission layer 213 forming material may not remain on the upper surface of the pixel definition layer 215. The thickness of the formed first emission layer 221, the thickness of the second emission layer 222, and the thickness of the third emission layer 223 may be uniform.

In an embodiment of the display apparatus manufacturing method, the lyophobic patterns LP1, LP2, and LP3 may be spaced apart from each other in the first direction (e.g., the x-axis direction or the −x-axis direction). Accordingly, the upper surface of the pixel definition layer 215 between the lyophobic patterns LP1, LP2, and LP3 may contact (e.g., directly contact) the opposite electrode 230. The adhesive force between the pixel definition layer 215 and the opposite electrode 230 may be improved. In an embodiment of the display apparatus manufacturing method according to an embodiment, the sub lyophobic patterns LP11 and LP12, LP21 and LP22, or LP31 and LP32 included in the lyophobic pattern LP1, LP2, or LP3 surrounding the opening OP1, OP2, or OP3 may be spaced apart from each other in the first direction (e.g., the x-axis direction or the −x-axis direction). The adhesive force between the portion of the pixel definition layer 215 disposed adjacent to the opening OP1, OP2, or OP3 and the opposite electrode 230 may be remarkably improved. Accordingly, the defect occurrence possibility in the manufacturing process may be reduced.

According to an embodiment of the display apparatus manufacturing method of the disclosure described above, the display apparatus 1 in which a defect occurrence possibility in a manufacturing process of the display apparatus is reduced and a method of manufacturing the same may be provided. However, the scope of the disclosure is not limited to these effects.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display apparatus comprising:
a first pixel electrode and a second pixel electrode spaced apart from each other and disposed on a substrate;
a pixel definition layer comprising:
a first inner surface defining a first opening exposing a portion of the first pixel electrode; and
a second inner surface defining a second opening exposing a portion of the second pixel electrode;
a first lyophobic pattern covering the first inner surface and a portion of an upper surface of the pixel definition layer adjacent to the first inner surface and comprising a lyophobic material; and
an opposite electrode disposed on the first pixel electrode and the second pixel electrode,
wherein the first lyophobic pattern partially surrounds the first opening in a plan view.

2. The display apparatus of claim 1, wherein the first lyophobic pattern comprises a first-first lyophobic pattern and a first-second lyophobic pattern spaced apart from each other.

3. The display apparatus of claim 2, wherein each of the first-first lyophobic pattern and the first-second lyophobic pattern surrounds a portion of the first opening in a plan view.

4. The display apparatus of claim 2, wherein a portion of an upper surface of the pixel definition layer between the first-first lyophobic pattern and the first-second lyophobic pattern directly contacts the opposite electrode.

5. The display apparatus of claim 1, further comprising:
a second lyophobic pattern covering the second inner surface and a portion of an upper surface of the pixel definition layer adjacent to the second inner surface and comprising a lyophobic material.

6. The display apparatus of claim 5, wherein a portion of an upper surface of the pixel definition layer between the first lyophobic pattern and the second lyophobic pattern directly contacts the opposite electrode.

7. The display apparatus of claim 5, wherein
the second lyophobic pattern comprises a second-first lyophobic pattern and a second-second lyophobic pattern spaced apart from each other, and
a portion of an upper surface of the pixel definition layer between the second-first lyophobic pattern and the second-second lyophobic pattern directly contacts the opposite electrode.

8. The display apparatus of claim 1, further comprising:
a first emission layer interposed between the first pixel electrode and the opposite electrode; and
a second emission layer interposed between the second pixel electrode and the opposite electrode.

9. The display apparatus of claim 1, wherein the lyophobic material comprises a self-assembled monolayer.

10. The display apparatus of claim 1, wherein the first lyophobic pattern is spaced apart from the first pixel electrode.

11. A method of manufacturing a display apparatus, the method comprising:
forming, on a substrate, a first pixel electrode and a second pixel electrode spaced apart from each other;
forming, on the substrate, a pixel definition layer comprising a first inner surface defining a first opening exposing a portion of the first pixel electrode and a second inner surface defining a second opening exposing a portion of the second pixel electrode;
forming a preliminary lyophobic pattern layer comprising a lyophobic material on the first pixel electrode, the second pixel electrode, and the pixel definition layer;
forming, by removing a portion of the preliminary lyophobic pattern layer, a first lyophobic pattern covering the first inner surface and a portion of an upper surface of the pixel definition layer adjacent to the first inner surface, comprising a lyophobic material, and partially surrounding the first opening in a plan view; and
forming an opposite electrode on the first pixel electrode and the second pixel electrode.

12. The method of claim 11, wherein the first lyophobic pattern comprises a first-first lyophobic pattern and a first-second lyophobic pattern spaced apart from each other.

13. The method of claim 12, wherein the forming of the first lyophobic pattern comprises forming the first lyophobic pattern such that each of the first-first lyophobic pattern and the first-second lyophobic pattern surrounds a portion of the first opening in a plan view.

14. The method of claim 12, wherein the forming of the opposite electrode comprises forming the opposite electrode such that a portion of an upper surface of the pixel definition layer between the first-first lyophobic pattern and the first-second lyophobic pattern directly contacts the opposite electrode.

15. The method of claim 11, wherein the forming of the first lyophobic pattern comprises forming, by removing a portion of the preliminary lyophobic pattern layer, a second lyophobic pattern covering the second inner surface and a portion of an upper surface of the pixel definition layer adjacent to the second inner surface.

16. The method of claim 15, wherein the forming of the opposite electrode comprises forming the opposite electrode such that a portion of an upper surface of the pixel definition layer between the first lyophobic pattern and the second lyophobic pattern directly contacts the opposite electrode.

17. The method of claim 15, wherein
the second lyophobic pattern comprises a second-first lyophobic pattern and a second-second lyophobic pattern spaced apart from each other, and
the forming of the opposite electrode comprises forming the opposite electrode such that a portion of an upper surface of the pixel definition layer between the second-first lyophobic pattern and the second-second lyophobic pattern directly contacts the opposite electrode.

18. The method of claim 11, further comprising:
forming a first emission layer in the first opening; and
forming a second emission layer in the second opening,
wherein the forming of the first emission layer and the forming of the second emission layer are performed between the forming of the first lyophobic pattern and the forming of the opposite electrode.

19. The method of claim 11, wherein the lyophobic material comprises a self-assembled monolayer.

20. The method of claim 11, wherein the forming of the first lyophobic pattern comprises forming the first lyophobic pattern such that the first lyophobic pattern is spaced apart from the first pixel electrode.
